(19) United States
(12) Patent Application Publication
(10) Pub. No.: US 2026/0150440 A1
(43) Pub. Date: May 28, 2026

(54) LIGHT EMITTING DEVICE INCLUDING AN ELECTRODE AND A REFLECTIVE FILM

(71) Applicant: SAMSUNG ELECTRONICS CO., LTD., Suwon-si (KR)

(72) Inventors: Inhyuk Kim, Suwon-si (KR); Jinho Park, Suwon-si (KR); Jaein Sim, Suwon-si (KR); Gyeongmi Lee, Suwon-si (KR); Donghyeong Lee, Suwon-si (KR); Joonwoo Jeon, Suwon-si (KR)

(73) Assignee: SAMSUNG ELECTRONICS CO., LTD., Suwon-si (KR)

(21) Appl. No.: 19/273,683

(22) Filed: Jul. 18, 2025

(30) Foreign Application Priority Data
Nov. 27, 2024 (KR) 10-2024-0172768

(51) Int. Cl. H10H 20/832; H10H 20/831

(52) U.S. Cl. CPC H10H 20/835; H10H 20/8312

(57) ABSTRACT

Provided is a light emitting device including a semiconductor light emitting structure including a first conductivity type semiconductor layer, an active layer, and a second conductivity type semiconductor layer sequentially stacked in a vertical direction, and an electrode layer on the second conductivity type semiconductor layer and spaced apart from the active layer in the vertical direction, wherein the electrode layer includes a transparent electrode layer in contact with the second conductivity type semiconductor layer, and a lower reflective electrode layer in contact with the transparent electrode layer and spaced apart from the second conductivity type semiconductor layer in the vertical direction, and wherein a minimum width of the lower reflective electrode layer in a horizontal direction is greater than a width of the transparent electrode layer in the horizontal direction.

### CROSS-REFERENCE TO RELATED APPLICATION

This application claims priority to Korean Patent Application No. 10-2024-0172768, filed on Nov. 27, 2024, in the Korean Intellectual Property Office, the disclosure of which is incorporated by reference herein in its entirety.

### BACKGROUND

Embodiments of the present disclosure relate to a light emitting device, and more particularly, to a light emitting device including an electrode and reflective film structure to improve a light output of a micro LED.

Light emitting diodes (LED) as light sources converting electrical energy into optical energy are widely used as light sources for various display devices such as lighting devices, televisions (TVs), mobile phones, personal computers (PCs), laptops, personal digital assistants (PDA), digital cameras, camcorders, viewfinders, microdisplays, 3D displays, and virtual reality or augmented reality displays. Recently, micro-or nano-sized ultra-small LEDs using II-VI or III-V group compound semiconductors have been developed, and there is a need to develop light-emitting devices with a new structure to improve light extraction efficiency (LEE) in the ultra-small LEDs.

### SUMMARY

One or more embodiments provide a light emitting device with improved reliability.

According to an aspect of one or more embodiments, there is provided a light emitting device including a semiconductor light emitting structure including a first conductivity type semiconductor layer, an active layer, and a second conductivity type semiconductor layer sequentially stacked in a vertical direction, and an electrode layer on the second conductivity type semiconductor layer and spaced apart from the active layer in the vertical direction, the second conductivity type semiconductor layer being between the electrode layer and the active layer, wherein the electrode layer includes a transparent electrode layer on the second conductivity type semiconductor layer, and a lower reflective electrode layer on the transparent electrode layer and spaced apart from the second conductivity type semiconductor layer in the vertical direction, the transparent electrode layer being between the lower reflective electrode layer and the second conductivity type semiconductor layer, and wherein a minimum width of the lower reflective electrode layer in a horizontal direction orthogonal to the vertical direction is greater than a width of the transparent electrode layer in the horizontal direction.

According to another aspect of one or more embodiments, there is provided a light emitting device including a first conductivity type base semiconductor layer, a semiconductor light emitting structure including a first conductivity type semiconductor layer, an active layer, and a second conductivity type semiconductor layer sequentially stacked on a main surface of the first conductivity type base semiconductor layer in a vertical direction perpendicular to the main surface, a transparent electrode layer on the second conductivity type semiconductor layer and spaced apart from the active layer in the vertical direction, the second conductivity type semiconductor layer being between the transparent electrode layer and the active layer, a lower reflective electrode layer on the transparent electrode layer and spaced apart from the second conductivity type semiconductor layer in the vertical direction, the transparent electrode layer being between the lower reflective electrode layer and the second conductivity type semiconductor layer, an insulating layer on the semiconductor light emitting structure, and a side reflective electrode layer spaced apart from the semiconductor light emitting structure in a horizontal direction orthogonal to the vertical direction, wherein a portion of the side reflective electrode layer penetrates at least a portion of the insulating layer.

According to still another aspect of one or more embodiments, there is provided a light emitting device including a first conductivity type base semiconductor layer, a semiconductor light emitting structure including a first conductivity type semiconductor layer, an active layer, and a second conductivity type semiconductor layer sequentially stacked on a main surface of the first conductivity type base semiconductor layer in a vertical direction perpendicular to the main surface, a first electrode on sidewalls of the first conductivity type base semiconductor layer, a transparent electrode layer on the second conductivity type semiconductor layer and spaced apart from the active layer in the vertical direction, the second conductivity type semiconductor layer being between the transparent electrode layer and the active layer, a lower reflective electrode layer on the transparent electrode layer and spaced apart from the second conductivity type semiconductor layer in the vertical direction, the transparent electrode layer being between the lower reflective electrode layer and the second conductivity type semiconductor layer, a second electrode on the transparent electrode layer and spaced apart from the second conductivity type semiconductor layer in the vertical direction, the transparent electrode layer being between the second electrode and the second conductivity type semiconductor layer, an etch stopper on sidewalls of the semiconductor light emitting structure, an insulating layer on the semiconductor light emitting structure, a side reflective electrode layer spaced apart from the semiconductor light emitting structure in a horizontal direction orthogonal to the vertical direction, and a microlens on a portion of a rear surface of the first conductivity type base semiconductor layer opposite to the main surface of the first conductivity type base semiconductor layer, the microlens being configured to extract light emitted from the semiconductor light emitting structure, wherein a minimum width of the lower reflective electrode layer in the horizontal direction is greater than a width of the transparent electrode layer in the horizontal direction, wherein a distance between a center of the side reflective electrode layer and a center of another side reflective electrode layer is greater than a maximum width of the lower reflective electrode layer in the horizontal direction, wherein a portion of the side reflective electrode layer penetrates at least a portion of the insulating layer, wherein at least a portion of the etch stopper is in physical contact with the lower reflective electrode layer, and wherein a level of a bottom surface of the transparent electrode layer in the vertical direction is uniform.

According to further still another aspect of one or more embodiments, there is provided a method of manufacturing a light emitting device, the method including forming a semiconductor light emitting structure including a first conductivity type semiconductor layer, an active layer, and a second conductivity type semiconductor layer sequentially in a vertical direction, providing an insulating layer on the semiconductor light emitting structure, etching a portion of the insulating layer and the first conductivity type semiconductor layer, providing an electrode layer on the second conductivity type semiconductor layer that is spaced apart from the active layer in the vertical direction, wherein forming of the electrode layer includes forming a transparent electrode layer on the second conductivity type semiconductor layer, and forming a lower reflective electrode layer on the transparent electrode layer and spaced apart from the second conductivity type semiconductor layer in the vertical direction, and a minimum width of the lower reflective electrode layer in a horizontal direction is greater than a width of the transparent electrode layer.

The method may further include forming a side reflective electrode layer spaced apart from the semiconductor light emitting structure in the horizontal direction, a portion of the side reflective electrode layer penetrating at least a portion of the insulating layer.

The method may further include forming a first conductivity type base semiconductor layer on a main surface of the first conductivity type semiconductor layer and spaced apart from the active layer in the vertical direction, wherein a level of a top surface of the side reflective electrode layer is greater than a level of the main surface in the vertical direction.

The method may further include forming an etch stopper on sidewalls of the semiconductor light emitting structure.

### BRIEF DESCRIPTION OF DRAWINGS

Embodiments will be more clearly understood from the following detailed description taken in conjunction with the accompanying drawings in which:

FIG. 1 is a cross-sectional view illustrating a schematic structure of a light emitting device according to one or more embodiments;

FIG. 2 is an enlarged view of a region A of FIG. 1;

FIG. 3 is a cross-sectional view illustrating a schematic structure of a light emitting device according to one or more other embodiments;

FIG. 4 is a schematic perspective view for explaining example shapes of a semiconductor light emitting structure and a transparent electrode layer illustrated in FIG. 3;

FIG. 5 is a schematic plan view of a semiconductor light emitting structure illustrated in FIG. 4;

FIG. 6 is a schematic perspective view for explaining example shapes of a semiconductor light emitting structure and a transparent electrode layer included in a light emitting device according to one or more other embodiments;

FIG. 7 is a schematic plan view of a semiconductor light emitting structure illustrated in FIG. 6;

FIG. 8 is a cross-sectional view illustrating a light emitting device according to one or more other embodiments;

FIG. 9 is a schematic plan view illustrating a light emitting device according to one or more embodiments;

FIG. 10 is an enlarged view of a region B of FIG. 9;

FIG. 11 is a schematic perspective view illustrating a display device according to one or more embodiments;

FIG. 12 is an enlarged plan view of a portion indicated by “C” in FIG. 11;

FIG. 13 is a cross-sectional view schematically illustrating components of a cross-section taken along line I-I′ of FIG. 11 and a cross-section taken along line II-II′ of FIG. 12;

FIGS. 14, 15, 16, 17, 18, 19, 20, 21, 22, 23, 24, and 25 are cross-sectional views illustrating a method of manufacturing a display device including a light emitting device according to one or more embodiments according to a process order;

FIG. 26 is a block diagram of one or more embodiments of an electronic device including a light emitting device or a display device according to one or more embodiments;

FIG. 27 is a view illustrating one or more embodiments of a mobile device as an application example of an electronic device including a light emitting device or a display device according to one or more embodiments;

FIG. 28 is a view illustrating one or more embodiments of an automobile head-up display device as an application example of an electronic device including a light emitting device or a display device according to one or more embodiments;

FIG. 29 is a view illustrating one or more embodiments of augmented reality glasses or virtual reality glasses as an application example of an electronic device including a light emitting device or a display device according to one or more embodiments;

FIG. 30 is a view illustrating one or more embodiments of a large signage as an application example of an electronic device including a light emitting device or a display device according to one or more embodiments; and

FIG. 31 is a view illustrating one or more embodiments of a wearable display as an application example of an electronic device including a light emitting device or a display device according to one or more embodiments.

### DETAILED DESCRIPTION

Hereinafter, embodiments will be described in detail with reference to the accompanying drawings. In the drawings, like reference characters denote like elements, and redundant descriptions thereof will be omitted.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Unless otherwise specified below, in the present specification, a vertical direction may be defined as a Z direction, and a first horizontal direction and a second horizontal direction may each be defined as a horizontal direction perpendicular to the Z direction. The first horizontal direction may be referred to as an X direction, and the second horizontal direction may be referred to as a Y direction. A vertical level may refer to a height level according to the vertical direction (Z direction). A horizontal width in the first horizontal direction may refer to a length in the horizontal direction (X direction and/or Y direction), and a vertical length may refer to a length in the vertical direction (Z direction).

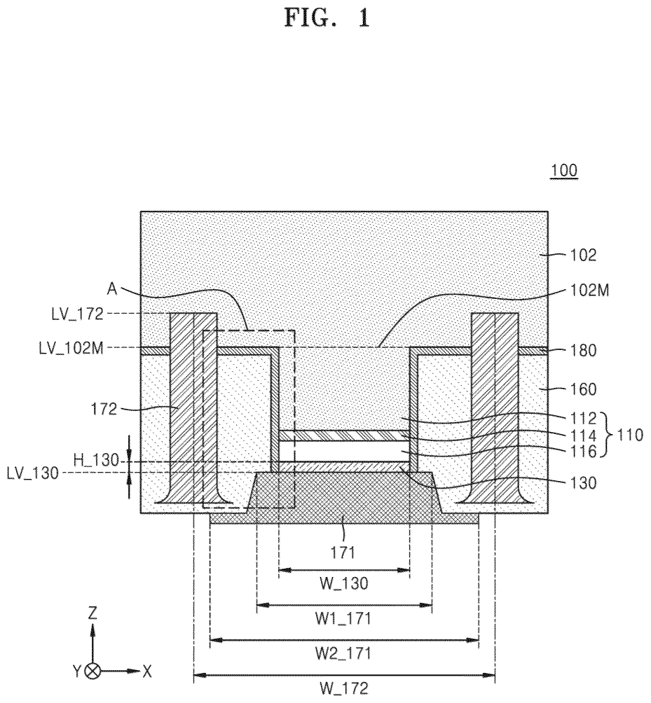

FIG. 1 is a cross-sectional view illustrating a schematic structure of a light emitting device 100 according to one or more embodiments.

Referring to FIG. 1, the light emitting device 100 may include a first conductivity type base semiconductor layer 102 and a semiconductor light emitting structure 110 arranged on a main surface 102M of the first conductivity type base semiconductor layer 102. The semiconductor light emitting structure 110 may include a first conductivity type semiconductor layer 112, an active layer 114, and a second conductivity type semiconductor layer 116 sequentially stacked on the main surface 102M of the first conductivity type base semiconductor layer 102 in a vertical direction (Z direction in FIG. 1) perpendicular to the main surface 102M.

The semiconductor light emitting structure 110 may include a micro light emitting diode (LED). In one or more embodiments, the semiconductor light emitting structure 110 may include a micro LED generating light of any one color selected from red, green, and blue. The term “micro LED” used in the present specification may refer to an LED having a width of about 100 μm or less in a horizontal direction (for example, X direction in FIG. 1) perpendicular to the vertical direction (Z direction in FIG. 1). For example, the width of the semiconductor light emitting structure 110 in the horizontal direction (for example, X direction in FIG. 1) may be about 100 μm or less, about 50 μm or less, about 20 μm or less, about 10 μm or less, about 6 μm or less, about 5 μm or less, about 4 μm or less, or about 2 μm or less. However, the inventive concept is not limited thereto.

The semiconductor light emitting structure 110 may emit light with a wavelength λ selected in a range of about 400 nm to about 700 nm.

In one or more embodiments, the semiconductor light emitting structure 110 may emit light with a first wavelength λ1 selected in a range of about 580 nm to about 700 nm. The light with the first wavelength λ1 may be red light. In the present specification, a wavelength region of red light refers to a wavelength region of about 580 nm or more and less than about 700 nm, for example, a wavelength region in a range of about 610 nm to about 650 nm, or a wavelength region in a range of about 620 nm to about 640 nm, and may have a peak of at least one emission spectrum in the wavelength region of red light.

In one or more other embodiments, the semiconductor light emitting structure 110 may emit light with a second wavelength λ2 selected in a range of about 490 nm to about 580 nm. The light with the second wavelength λ2 may be green light. In the present specification, a wavelength region of green light refers to a wavelength region of about 490 nm or more and less than about 580 nm, for example, a wavelength region in a range of about 510 nm to about 550 nm, or a wavelength region in a range of about 520 nm to about 540 nm, and may have a peak of at least one emission spectrum in the wavelength region of green light.

In one or more other embodiments, the semiconductor light emitting structure 110 may emit light with a third wavelength λ3 selected in a range of about 400 nm to about 490 nm. The light with the third wavelength λ3 may be blue light. In the present specification, a wavelength region of blue light refers to a wavelength region of about 400 nm or more and less than about 490 nm, for example, a wavelength region in a range of about 440 nm to about 480 nm, or a wavelength region in a range of about 450 nm to about 470 nm, and may have a peak of at least one emission spectrum in the wavelength region of blue light.

Each of the first conductivity type base semiconductor layer 102, the first conductivity type semiconductor layer 112, the active layer 114, and the second conductivity type semiconductor layer 116 may include an epitaxial nitride semiconductor layer. The first conductivity type base semiconductor layer 102 and the first conductivity type semiconductor layer 112 may include a nitride semiconductor layer doped with the same conductivity type dopant, for example, an n-type dopant, and an average doping concentration of the first conductivity type base semiconductor layer 102 may be greater than an average doping concentration of the first conductivity type semiconductor layer 112. Each of the first conductivity type semiconductor layer 112 and the second conductivity type semiconductor layer 116 may include a single layer or a multilayer including a plurality of layers having different dopant concentrations and component compositions. The first conductivity type base semiconductor layer 102 may be spaced apart from the active layer 114 in the vertical direction (Z direction in FIG. 1) with the first conductivity type semiconductor layer 112 therebetween.

The first conductivity type base semiconductor layer 102 may have a thickness of about 10 nm to about 6,000 nm in the vertical direction (Z direction in FIG. 1). The first conductivity type semiconductor layer 112 may have a thickness of about 10 nm to about 500 nm in the vertical direction.

In the semiconductor light emitting structure 110, the first conductivity type semiconductor layer 112 may have a structure integrally connected to the first conductivity type base semiconductor layer 102. In one or more embodiments, the first conductivity type base semiconductor layer 102 and the first conductivity type semiconductor layer 112 may include the same material. In one or more embodiments, the first conductivity type base semiconductor layer 102 may include n-type gallium nitride (n-GaN). The first conductivity type semiconductor layer 112 may include an n-type superlattice structure layer. For example, the first conductivity type semiconductor layer 112 may include an indium gallium nitride/gallium nitride (InGaN/GaN) superlattice structure layer. In this case, the first conductivity type semiconductor layer 112 may have a superlattice structure in which InGaN layers and GaN layers are alternately stacked one by one. In the first conductivity type semiconductor layer 112, the superlattice structure may include a pair structure of an InGaN layer and a GaN layer in about 10 cycles to about 50 cycles, for example, about 15 cycles to about 20 cycles. However, the inventive concept is not limited thereto.

In one or more other embodiments, the first conductivity type semiconductor layer 112 may include a nitride semiconductor layer having a composition of InₓAl_{y}Ga_{(1-x-y)}N (0≤x<1, 0≤y<1, and 0≤x+y<1). In one or more other embodiments, the first conductivity type semiconductor layer 112 may include n-type gallium nitride (n-GaN) doped with silicon (Si), germanium (Ge), or carbon (C). In one or more other embodiments, the first conductivity type semiconductor layer 112 may include a semiconductor layer of aluminum indium gallium phosphide (AlInGaP) or aluminum indium gallium arsenide (AlInGaAs).

In the semiconductor light emitting structure 110, the active layer 114 may emit light having a predetermined energy by recombination of electrons and holes. The active layer 114 may have a multi-quantum well (MQW) structure in which a quantum barrier layer and a quantum well layer are alternately stacked.

In one or more embodiments, the active layer 114 may include a quantum barrier layer and a quantum well layer including a compound semiconductor of group III-V elements. For example, the active layer 114 may include any one pair structure selected from InGaN/GaN, InGaN/InGaN, indium gallium nitride/aluminum gallium nitride (InGaN/AlGaN), and indium gallium nitride/indium aluminum gallium nitride (InGaN/InAlGaN). However, embodiments are not limited thereto.

In the vertical direction (Z direction in FIG. 1), a thickness of the active layer 114 may be less than about 300 nm. As illustrated in FIG. 1, the active layer 114 may have a surface in contact with the first conductivity type semiconductor layer 112 and a surface in contact with the second conductivity type semiconductor layer 116, and the shortest distance from the surface of the active layer 114 in contact with the first conductivity type semiconductor layer 112 to the surface of the active layer 114 in contact with the second conductivity type semiconductor layer 116 may be less than about 300 nm.

In one or more embodiments, the thickness of the active layer 114 may be less than about 300 nm, less than about 200 nm, less than about 100 nm, less than about 50 nm, less than about 40 nm, less than about 20 nm, less than about 10 nm, less than about 5 nm, or less than about 3 nm. For example, the thickness of the active layer 114 may be selected in a range of about 2 nm to about 10 nm. However, embodiments are not limited thereto.

In the semiconductor light emitting structure 110, the second conductivity type semiconductor layer 116 may include a nitride semiconductor layer doped with a p-type dopant. In one or more embodiments, the second conductivity type semiconductor layer 116 may include a nitride semiconductor layer having a composition of InₓAl_{y}Ga_{(1-x-y)}N (0≤x<1, 0≤y<1, and 0≤x+y<1). For example, the second conductivity type semiconductor layer 116 may include p-type gallium nitride (p-GaN) doped with Mg or Zn. However, embodiments are not limited thereto. In one or more other embodiments, the second conductivity type semiconductor layer 116 may include a semiconductor layer of AlInGaP or AlInGaAs.

The light emitting device 100 may include a transparent electrode layer 130 and a lower reflective electrode layer 171 provided on and covering the second conductivity type semiconductor layer 116. The transparent electrode layer 130 may be in contact with the second conductivity type semiconductor layer 116 and may be spaced apart from the active layer 114 in the vertical direction (Z direction in FIG. 1) with the second conductivity type semiconductor layer 116 between the transparent electrode layer 130 and the active layer 114.

The lower reflective electrode layer 171 may be in contact with the transparent electrode layer 130, and may be spaced apart from the second conductivity type semiconductor layer 116 in the vertical direction (Z direction in FIG. 1) with the transparent electrode layer 130 between the second conductivity type semiconductor layer 116 and the lower reflective electrode layer 171. In the present specification, the transparent electrode layer 130 may be referred to as an electrode layer, and the lower reflective electrode layer 171 may be referred to as an electrode layer or a second electrode.

The shortest distance from the lower reflective electrode layer 171 to the active layer 114 in the vertical direction may be determined according to a wavelength λ of light emitted from the semiconductor light emitting structure 110. The shortest distance from the lower reflective electrode layer 171 to the active layer 114 in the vertical direction may be greater than 0.05λ and less than 0.4λ. In one or more embodiments, the shortest distance from the lower reflective electrode layer 171 to the active layer 114 in the vertical direction may be greater than 0.05λ and less than 0.24λ. A thickness of the lower reflective electrode layer 171 in the vertical direction (Z direction), a thickness H_130 of the transparent electrode layer 130, and the shortest distance from the lower reflective electrode layer 171 to the active layer 114 may be set to a thickness and distance that may maximize cavity effect, and values may be set differently according to the wavelength of light.

As illustrated in FIG. 1, the second conductivity type semiconductor layer 116 may have a surface in contact with the active layer 114 and a surface in contact with the transparent electrode layer 130, and the surface in contact with the active layer 114 and the surface in contact with the transparent electrode layer 130 are opposite to each other in the vertical direction. In this way, when the second conductivity type semiconductor layer 116 is between the active layer 114 and the transparent electrode layer 130 and is in contact with the active layer 114 and the transparent electrode layer 130, the shortest distance from the lower reflective electrode layer 171 to the active layer 114 in the vertical direction corresponds to the thickness of the second conductivity type semiconductor layer 116 in the vertical direction, and the thickness of the second conductivity type semiconductor layer 116 may be greater than 0.05λ and less than 0.4λ. In one or more embodiments, a thickness of the second conductivity type semiconductor layer 116 in the vertical direction may be greater than 0.05λ and less than 0.24λ. The lower reflective electrode layer 171 may be an electrode of the second conductivity type semiconductor layer 116.

When the semiconductor light emitting structure 110 is configured to emit red light having a first wavelength λ1 selected in a range of about 580 nm to about 700 nm, the thickness of the second conductivity type semiconductor layer 116 in the vertical direction may be selected in a range greater than 0.05λ and less than 0.24λ, for example, a range greater than 0.05λ and less than 0.25λ.

When the semiconductor light emitting structure 110 is configured to emit green light having a second wavelength λ2 selected in a range of about 490 nm to about 580 nm, the thickness of the second conductivity type semiconductor layer 116 in the vertical direction may be selected in a range greater than 0.05λ and less than 0.24λ, for example, a range greater than 0.1λ and less than 0.25λ.

When the semiconductor light emitting structure 110 is configured to emit blue light having a third wavelength λ3 selected in a range of about 400 nm to about 490 nm, the thickness of the second conductivity type semiconductor layer 116 in the vertical direction may be selected in a range greater than 0.05λ and less than 0.4λ, for example, a range greater than 0.2λ and less than 0.4λ.

The semiconductor light emitting structure 110 may have a pillar shape with a central axis extending in the vertical direction. The semiconductor light emitting structure 110 may have a width less than 100 μm in a first horizontal direction (for example, X direction in FIG. 1) orthogonal to the vertical direction. In embodiments, the width of the semiconductor light emitting structure 110 may be about 100 nm or more and about 10 μm or less, or about 500 nm or more and about 1500 nm or less.

The transparent electrode layer 130 may have a width W_130 that is the same as or similar to the width of the semiconductor light emitting structure 110 in the first horizontal direction (for example, X direction in FIG. 1). In the vertical direction, the transparent electrode layer 130 may have a variable thickness. A portion of the transparent electrode layer 130 in contact with the lower reflective electrode layer 171 may have a thickness less in the vertical direction (Z direction) than other portions of the transparent electrode layer 130. In one or more embodiments, the maximum thickness of the transparent electrode layer 130 in the vertical direction may be about 50 nm to about 150 nm, and a portion of the transparent electrode layer 130 in contact with the lower reflective electrode layer 171 may have a thickness of about 30 nm to about 70 nm. However, embodiments are not limited thereto.

The width of the lower reflective electrode layer 171 in the vertical direction is illustrated as being greater than the width of the transparent electrode layer 130 in the vertical direction. However, the width of each component is not limited to the drawing. In one or more embodiments, a width of the lower reflective electrode layer 171 in the vertical direction may be equal to or less than a width of the transparent electrode layer 130 in the vertical direction.

The transparent electrode layer 130 may include a transparent conductive material. In embodiments, the transparent electrode layer 130 may include indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In4Sn3O12, zinc magnesium oxide (Zn(1-x)MgxO) (0≤x≤1), or a combination thereof. The thickness of the transparent electrode layer 130 in the first horizontal direction (X direction) may be about 1 nm to about 100 nm, for example, about 7 nm to about 20 nm. However, embodiments are not limited thereto.

The lower reflective electrode layer 171 may include silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), titanium (Ti), titanium nitride (TiN), tantalum (Ta), tantalum nitride (TaN), tungsten (W), or a combination thereof. However, embodiments are not limited thereto.

The width of the lower reflective electrode layer 171 in the horizontal direction may increase in a direction away from the transparent electrode layer 130. In one or more embodiments, the width of the lower reflective electrode layer 171 in the horizontal direction may be greater in a region lower than the insulating layer 160 than in a region at the same vertical level as the insulating layer 160.

A top surface of the lower reflective electrode layer 171 may be in physical contact with a bottom surface of the transparent electrode layer 130. A vertical level LV_130 of the bottom surface of the transparent electrode layer 130 may be conformally and uniformly formed. The bottom surface of the transparent electrode layer 130 as a region corresponding to a channel, in which the lower reflective electrode layer 171 is formed, may be etched during a process. The lower reflective electrode layer 171 may be formed on a region in which the transparent electrode layer 130 is etched.

By controlling the thickness of the transparent electrode layer 130, the aforementioned cavity effect may be amplified to increase light efficiency.

The minimum width W1_171 of the lower reflective electrode layer 171 in the horizontal direction may be greater than the width W_130 of the transparent electrode layer 130. Therefore, the bottom surface of the transparent electrode layer 130 may be completely overlapped by the lower reflective electrode layer 171, but the top surface of the lower reflective electrode layer 171 may not be completely overlapped by the transparent electrode layer 130 and partially exposed by the transparent electrode layer 130. For example, the lower reflective electrode layer 171 may be provided on and cover the entire bottom surface of the transparent electrode layer 130. A portion of the top surface of the lower reflective electrode layer 171 that is not overlapped by the transparent electrode layer 130 may be provided on and covered with an etch stopper 180 and the insulating layer 160.

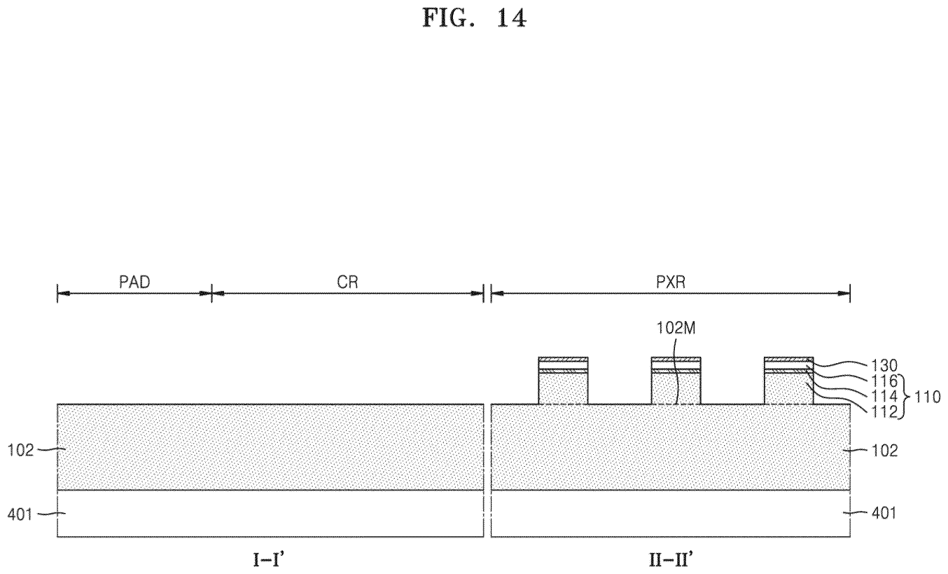

The light emitting device 100 may further include the etch stopper 180 adjacent to and surrounding a sidewall of the semiconductor light emitting structure 110. For example, the etch stopper 180 may be at a side of the semiconductor light emitting structure 110 in the horizontal direction. The etch stopper 180 may be formed before the insulating layer 160. In one or more embodiments, the etch stopper 180 may be formed prior to the lower reflective electrode layer 171. The etch stopper 180 may serve as an etching stop layer to prevent over-etching when etching is performed to create a region in which the lower reflective electrode layer 171 is formed. In one or more embodiments, the etch stopper 180 may include aluminum oxide. The process order of the etch stopper 180 will be described in detail with reference to FIGS. 14 to 25.

The light emitting device 100 may further include a side reflective electrode layer 172 spaced apart from the semiconductor light emitting structure 110 in the horizontal direction orthogonal to the vertical direction. In the present specification, the side reflective electrode layer 172 may be referred to as a first electrode. For example, the side reflective electrode layer 172 may be an electrode of the first conductivity type semiconductor layer 112.

In one or more embodiments, the side reflective electrode layer 172 may be formed after the etch stopper 180 and the insulating layer 160 are formed. After the side reflective electrode layer 172 is formed, the insulating layer 160 may be further formed to be provided on and cover part of the side reflective electrode layer 172. For example, a portion of the side reflective electrode layer 172 may penetrate a portion of the insulating layer 160.

The width of the side reflective electrode layer 172 in the horizontal direction may be constant. However, because a partial region of the side reflective electrode layer 172 is deposited on the insulating layer 160, the width of the partial region of the side reflective electrode layer 172 in the horizontal direction may not be constant. In one or more embodiments, in the case of a portion of the side reflective electrode layer 172 close to the lower reflective electrode layer 171, a width in the horizontal direction may not be constant.

The side reflective electrode layer 172 may include silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), or a combination thereof.

The side reflective electrode layer 172 may be arranged through partial regions of the insulating layer 160 and the etch stopper 180. In one or more embodiments, a vertical level LV_172 of a top surface of the side reflective electrode layer 172 may be greater than a vertical level of the main surface 102M. In one or more embodiments, the top surface of the side reflective electrode layer 172 may be covered with the first conductivity type base semiconductor layer 102.

Therefore, the side reflective electrode layer 172 may be arranged in a spacer. The side reflective electrode layer 172 may serve as a reflective layer as well as the first electrode. In one or more embodiments, the side reflective electrode layer 172 may operate as a reflective film for light that travels to be reflected inside the semiconductor light emitting structure 110 or light reflected from the top surface of the lower reflective electrode layer 171. In addition, the side reflective electrode layer 172 together with the lower reflective electrode layer 171 may prevent light leakage and improve vertical light emission characteristics.

The side reflective electrode layers 172 may be spaced apart from each other in the horizontal direction. As described later, the side reflective electrode layers 172 are formed simultaneously, but are not arranged integrally, but may be spaced apart from each other. In one or more embodiments, the side reflective electrode layers 172 may be spaced apart from each other in the horizontal direction with the semiconductor light emitting structure 110 therebetween.

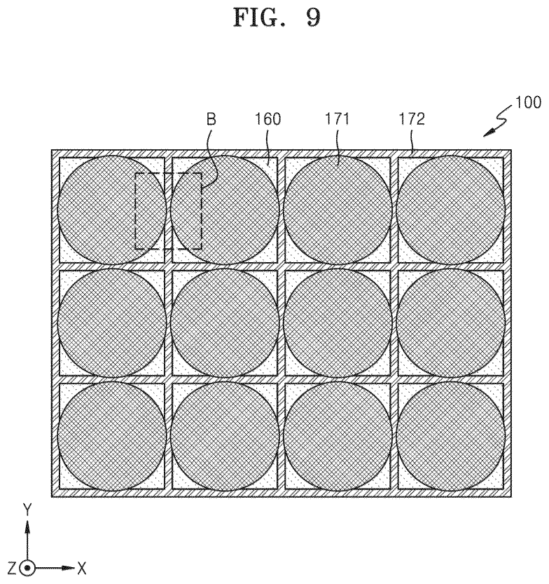

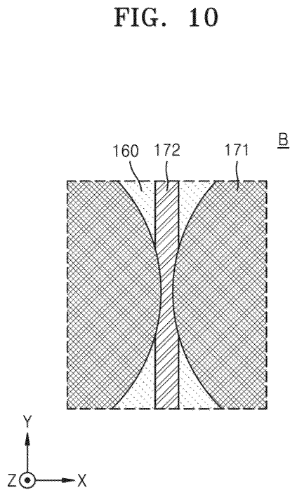

In one or more embodiments, a distance W_172 between the centers of the side reflective electrode layers 172 may be greater than the maximum width W2_171 of the lower reflective electrode layer 171 in the horizontal direction. Here, a portion defining both ends of W_172 may correspond to a central axis in the horizontal direction of each side reflective electrode layer 172. Therefore, when viewed from the vertical direction, partial regions of the lower reflective electrode layer 171 and partial regions of the side reflective electrode layer 172 may overlap each other. The overlapping of the lower reflective electrode layer 171 and the side reflective electrode layer 172 is described in detail with reference to FIGS. 9 and 10.

From a planar perspective (X-Y plane in FIG. 1), the semiconductor light emitting structure 110 may have various planar shapes. For example, the semiconductor light emitting structure 110 may have a circular, elliptical, or polygonal planar shape. The polygon may be a square, a hexagon, or an octagon. However, embodiments are not limited thereto. From a planar perspective (X-Y plane in FIG. 1), a planar shape of the transparent electrode layer 130 may be the same as or similar to the planar shape of the semiconductor light emitting structure 110. The semiconductor light emitting structure 110 and the transparent electrode layer 130 may form a single pillar shape.

Sidewalls of each of the first conductivity type semiconductor layer 112, the active layer 114, and the second conductivity type semiconductor layer 116 included in the semiconductor light emitting structure 110 and sidewalls of the transparent electrode layer 130 are coplanar.

The light emitting device 100 may include the insulating layer 160 provided on and covering the semiconductor light emitting structure 110 and forming the spacer. In one or more embodiments, the insulating layer 160 may include silicon oxide or a combination thereof. For example, the insulating layer 160 may include tetraethyl orthosilicate (TEOS), undoped silicate glass (USG), phosphosilicate glass (PSG), borosilicate glass (BSG), borophosphosilicate glass (BPSG), fluoride silicate glass (FSG), spin on glass (SOG), polysilazane, or a combination thereof.

The lower reflective electrode layer 171 may be provided on and cover a partial region of the insulating layer 160 and may be in contact with the transparent electrode layer 130. The lower reflective electrode layer 171 may include portions in contact with the insulating layer 160 and portions in contact with a reflective structure 150.

According to the light emitting device 100 described with reference to FIG. 1, by controlling the thickness of the second conductivity type semiconductor layer 116 according to the wavelength of light emitted from the semiconductor light emitting structure 110, the active layer 114 may be arranged in the semiconductor light emitting structure 110 to optimize light extraction efficiency (LEE) of the light emitting device 100, thereby maximizing the LEE from the light emitting device 100. In addition, the semiconductor light emitting structure 110 constitutes a micro LED having a width of about 100 μm or less, and the active layer 114 in the semiconductor light emitting structure 110 may have a multi-quantum well structure so as to be optimized for a micro-sized chip including the micro LED. Therefore, according to the inventive concept, it is possible to provide a light emitting device 100 having a structure optimized for a micro-sized chip.

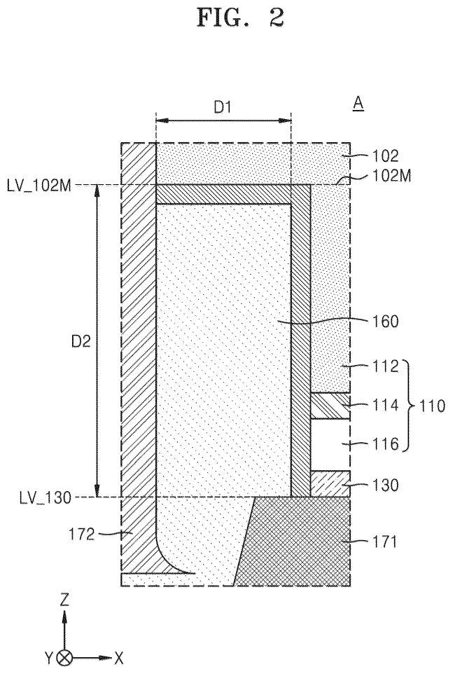

FIG. 2 is an enlarged view of a region A of FIG. 1.

FIG. 2 is referred to together with FIG. 1 and description previously given with reference to FIG. 1 is omitted. The side reflective electrode layer 172 may be spaced apart from the semiconductor light emitting structure 110 in the horizontal direction. In one or more embodiments, a horizontal distance between the side reflective electrode layer 172 and the semiconductor light emitting structure 110 may be referred to as D1. A distance between the top surface of the lower reflective electrode layer 171 and the main surface 102M may be referred to as D2. D1 may be less than D2. That is, when the light reflected from the lower reflective electrode layer 171 reaches the side reflective electrode layer 172, a range of an angle at which the light is reflected may be maximized to prevent light leakage as much as possible. A magnitude relationship between D1 and D2 is as described in the present specification, but a ratio of D1 and D2 may be determined differently according to a wavelength of the reflected light and a refractive index of the semiconductor light emitting structure 110. Note that D2 starts from the main surface and does not start from a bottom surface of the etch stopper 180. D2 starts from the top surface of the lower reflective electrode layer 171, and the top surface of the lower reflective electrode layer 171 may correspond to a vertical level LV_130 of the bottom surface of the transparent electrode layer 130.

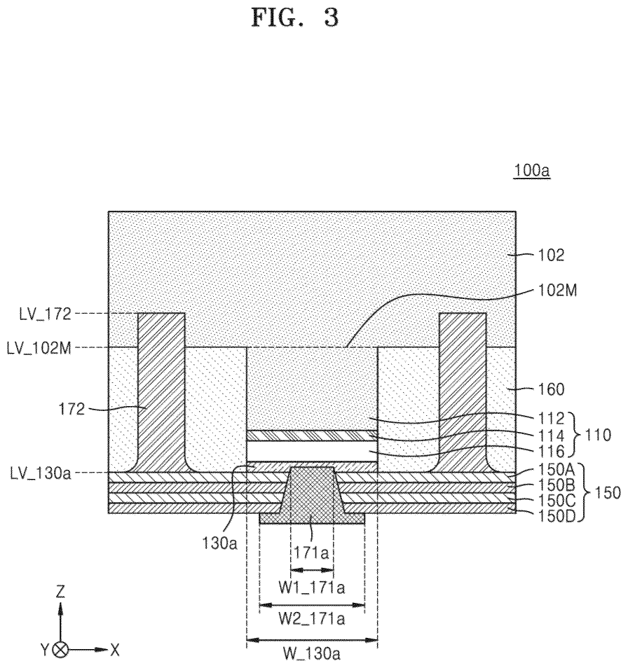

FIG. 3 is a cross-sectional view illustrating a schematic structure of a light emitting device 100a according to one or more other embodiments.

FIG. 3 will be described with reference to FIGS. 1 and 2. Contents overlapping those described in FIGS. 1 and 2 are omitted.

The light emitting device 100a may further include a reflective structure 150. The reflective structure 150 may be provided on and cover bottom surfaces of the semiconductor light emitting structure 110, the insulating layer 160, and the side reflective electrode layer 172.

The reflective structure 150 may include a distributed Bragg reflector (DBR). As illustrated in FIG. 3, the reflective structure 150 may have a distributed Bragg reflective layer structure in which a first insulating layer 150A, a second insulating layer 150B, a third insulating layer 150C, and a fourth insulating layer 150D are sequentially stacked. Here, the first insulating layer 150A and the third insulating layer 150C may include a first insulating material, and the second insulating layer 150B and the fourth insulating layer 150D may include a second insulating material. The first insulating material and the second insulating material may have different refractive indices. In embodiments, the first insulating material and the second insulating material may include different materials selected from silicon oxide (SiO2), silicon oxynitride (SiON), titanium oxide (TiO2), silicon nitride (Si3N4), aluminum oxide (Al2O3), titanium nitride (TiN), aluminum nitride (AlN), zirconium oxide (ZrO2), titanium aluminum nitride (TiAlN), titanium silicon nitride (TiSiN), hafnium oxide (HfO), niobium oxide (NbO2), tantalum oxide (TaO2), and magnesium fluoride (MgF2). The first insulating layer 150A of the reflective structure 150 may be in contact with sidewalls of each of the semiconductor light emitting structure 110 and the transparent electrode layer 130. The first insulating layer 150A may include a material having enhanced total reflection characteristics. In one or more embodiments, the first insulating layer 150A may include an insulating material having a refractive index equal to or less than that of the semiconductor light emitting structure 110 and/or the transparent electrode layer 130. For example, the first insulating layer 150A may include SiO2 or MgF2. However, embodiments are not limited thereto. Each of the first insulating layer 150A, the second insulating layer 150B, the third insulating layer 150C, and the fourth insulating layer 150D of the reflective structure 150 may have a thickness of about 10 nm to about 200 nm in the vertical direction.

The reflective structure 150 may control light distribution by reflecting light traveling from the inside of the semiconductor light emitting structure 110 toward a bottom surface of the semiconductor light emitting structure 110. Because the reflective structure 150 includes the DBR, the reflective structure 150 may act as a band pass filter (BPF) suppressing transmission of light of a specific wavelength, and because a difference in transmittance occurs according to an angle of incidence, light distribution may be more effectively controlled. In addition, the reflective structure 150 may significantly increase intensity of light emitted from a specific region by using the difference in transmittance according to the angle of incidence of light emitted from the semiconductor light emitting structure 110.

A lower reflective electrode layer 171a may penetrate the reflective structure 150 in the vertical direction to be in contact with the transparent electrode layer 130. The reflective electrode layer 170 may include portions in contact with the insulating layer 160 and portions in contact with the reflective structure 150.

The lower reflective electrode layer 171a penetrating the reflective structure 150 and the lower reflective electrode layer 171 illustrated in FIG. 1 may have different widths in the horizontal direction.

The lower reflective electrode layer 171a may be formed by not only penetrating the reflective structure 150, but also etching a partial region of the transparent electrode layer 130a to form a groove. Therefore, a vertical level LV_130a of the bottom surface of the transparent electrode layer 130a may not be conformal. A region, in which a top surface of the lower reflective electrode layer 171a is arranged, may be covered with the transparent electrode layer 130a.

The width of the lower reflective electrode layer 171a in the horizontal direction may increase as a distance from the transparent electrode layer 130a increases. Each of the minimum width W1_171a and the maximum width W2_171a of the width of the lower reflective electrode layer 171a in the horizontal direction may be less than a width W_130a of the transparent electrode layer 130a in the horizontal direction.

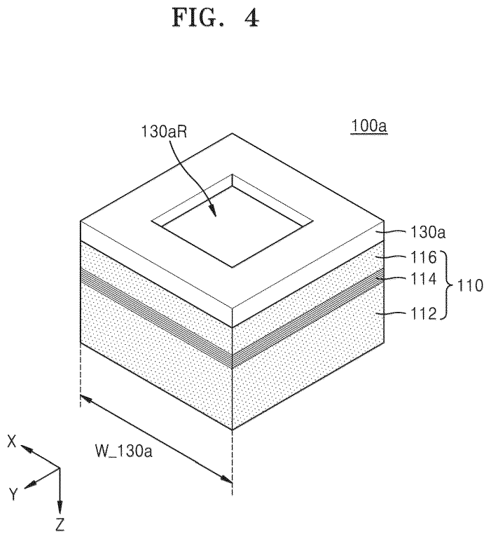

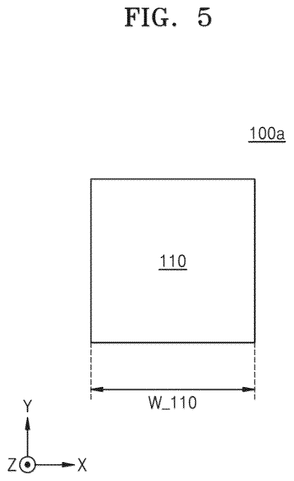

FIG. 4 is a schematic perspective view for explaining example shapes of a semiconductor light emitting structure and a transparent electrode layer illustrated in FIG. 3. FIG. 5 is a schematic plan view of a semiconductor light emitting structure illustrated in FIG. 4.

Referring to FIGS. 4 and 5 together with FIGS. 1 to 3.

From a planar perspective (X-Y plane in FIG. 1), each of the first conductivity type semiconductor layer 112, the active layer 114, the second conductivity type semiconductor layer 116, and the transparent electrode layer 130a included in the semiconductor light emitting structure 110 may have a rectangular planar shape. In the horizontal direction (for example, X or Y direction) parallel to the main surface 102M (refer to FIG. 1) of the first conductivity type base semiconductor layer 102, a width W_110 of the semiconductor light emitting structure 110 may correspond to the width W_130a of the transparent electrode layer 130a. In other words, in the horizontal direction (for example, X or Y direction) parallel to the main surface 102M of the first conductivity type base semiconductor layer 102, the transparent electrode layer 130a may have a width equal to or similar to the width W_110 of the semiconductor light emitting structure 110.

The width W_130a of the transparent electrode layer 130 a may be about 100 μm or less, about 50 μm or less, about 20 μm or less, about 10 μm or less, about 6 μm or less, about 5 μm or less, about 4 μm or less, or about 2 μm or less. However, embodiments are not limited thereto.

A local recess 130aR may be formed on a surface of the transparent electrode layer 130a opposite to a surface in contact with the semiconductor light emitting structure 110. Part of the lower reflective electrode layer 171a illustrated in FIG. 3 may be accommodated in the local recess 130aR of the transparent electrode layer 130a.

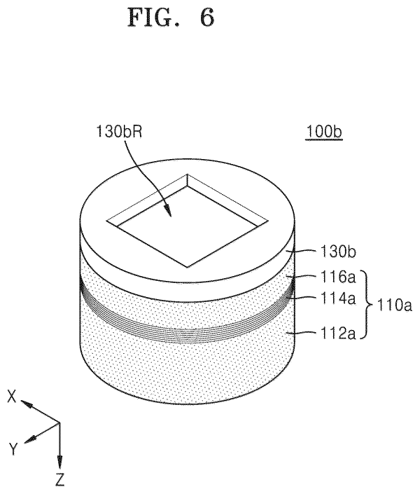

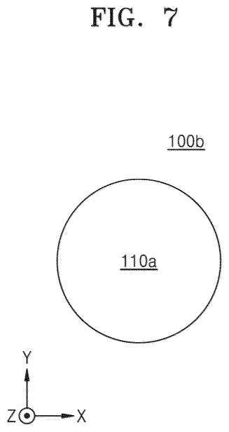

FIG. 6 is a schematic perspective view for explaining example shapes of a semiconductor light emitting structure and a transparent electrode layer included in a light emitting device according to one or more other embodiments. FIG. 7 is a schematic plan view of a semiconductor light emitting structure illustrated in FIG. 6.

FIGS. 6 and 7 will be described with reference to FIGS. 1 to 5.

FIGS. 6 and 7 are diagrams for explaining a light emitting device 100b according to one or more other embodiments, and FIG. 6 is a schematic perspective view for explaining an example shape of a semiconductor light emitting structure 110a and a transparent electrode layer 130b included in the light emitting device 100b, and FIG. 7 is a schematic plan view for explaining a planar shape of the semiconductor light emitting structure 110b. In FIGS. 6 and 7, the same reference numerals as in FIGS. 1 and 3 denote the same members, and detailed descriptions thereof will be omitted.

Referring to FIGS. 6 and 7, the light emitting device 100b may have substantially the same configuration as described for the light emitting device 100 with reference to FIG. 1. However, the light emitting device 100b includes the semiconductor light emitting structure 110a instead of the semiconductor light emitting structure 110. The semiconductor light emitting structure 110a may include a first conductivity type semiconductor layer 112a, an active layer 114a, and a second conductivity type semiconductor layer 116a.

The first conductivity type semiconductor layer 112a, the active layer 114a, and the second conductivity type semiconductor layer 116a may have substantially the same configurations as described for the first conductivity type semiconductor layer 112, the active layer 114, and the second conductivity type semiconductor layer 116 with reference to FIGS. 1, 2, and 3. From a planar perspective (X-Y plane), each of the first conductivity type semiconductor layer 112a, the active layer 114a, and the second conductivity type semiconductor layer 116a included in the semiconductor light emitting structure 110a may have, for example, a circular planar shape.

The semiconductor light emitting structure 110a may have a circular planar shape from a planar perspective as illustrated in FIG. 7, which is only one embodiment, and may have another shape. In one or more embodiments, the semiconductor light emitting structure 110a may have a rectangular planar shape having rounded corners from a planar perspective (X-Y plane). In one or more embodiments, the semiconductor light emitting structure 110a may have a hexagonal planar shape from a planar perspective (X-Y plane).

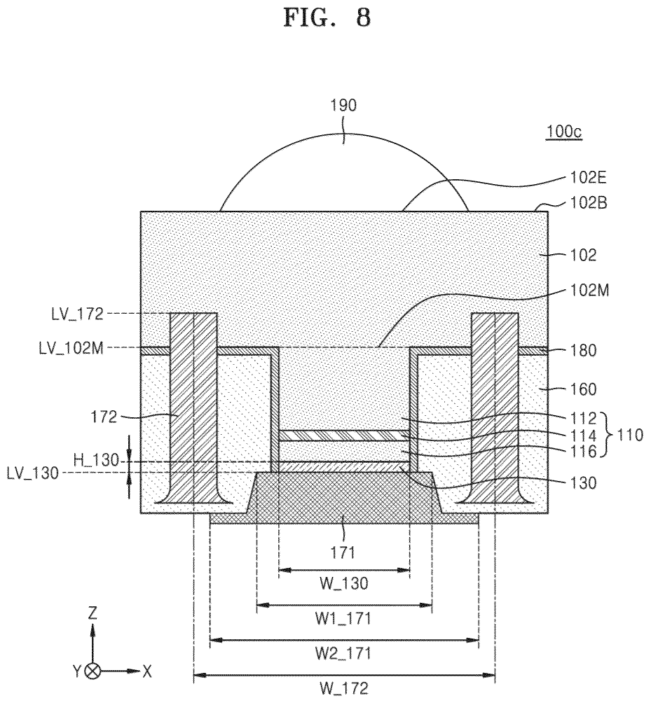

FIG. 8 is a cross-sectional view illustrating a light emitting device 100c according to one or more other embodiments.

Referring to FIG. 8, the light emitting device 100c may have substantially the same configuration as described for the light emitting device 100 with reference to FIG. 1. However, the light emitting device 100c further includes a microlens 190.

The microlens 190 may extract light emitted from the semiconductor light emitting structure 110. The microlens 190 may be spaced apart from the first conductivity type semiconductor layer 112 in a vertical direction (Z direction in FIG. 8) with the first conductivity type base semiconductor layer 102 therebetween. The first conductivity type base semiconductor layer 102 may be in contact with the main surface 102M in contact with the first conductivity type semiconductor layer 112 and the light emitting surface 102E that is part of a rear surface 102B that is the opposite surface of the main surface 102M. The microlens 190 may be disposed to overlap the semiconductor light emitting structure 110 in the vertical direction. The light emitting device 100c may further include the microlens 190 to improve LEE of the light emitting device 100c.

In one or more embodiments, the microlens 190 may include a spherical microlens or an aspherical microlens. In embodiments, the microlens 190 may include a graded refractive index layer formed in a multilayer structure in which a refractive index gradually decreases in a light traveling direction. The graded refractive index layer may be formed by using an oblique deposition method, a sputtering method, or an evaporation method. The graded refractive index layer may be configured so that the refractive index gradually decreases in a direction of a light emission surface. In embodiments, the microlens 190 may include titanium oxide (TiO2), silicon carbide (SiC), gallium nitride (GaN), gallium phosphide (GaP), SiN, SiON, ZrO2, indium tin oxide (ITO), aluminum nitride (AlN), aluminum oxide (Al2O3), MgO, SiO2, calcium fluoride (CaF2), MgF2, or a combination thereof. However, embodiments are not limited thereto.

FIG. 9 is a schematic plan view illustrating a light emitting device 100 according to one or more embodiments. FIG. 10 is an enlarged view of a region B of FIG. 9.

Refer to FIG. 9 together with FIG. 1. The lower reflective electrode layers 171 included in the light emitting device 100 may be spaced apart from each other in the horizontal direction. Although the side reflective electrode layers 172 are illustrated as being connected to each other and formed integrally in a plan view, the side reflective electrode layers 172 may be separated from each other in a subsequent process.

In one or more embodiments, a top surface of the lower reflective electrode layer 171 has a circular shape. However, embodiments are not limited thereto. The top surface of the lower reflective electrode layer 171 may be not only circular, but also have a square shape with rounded corners. An area of the lower reflective electrode layer 171 and a thickness of the side reflective electrode layer 172 illustrated in FIG. 9 are not limited to the drawing.

From a planar perspective, at least a portion of the lower reflective electrode layer 171 and a portion of the side reflective electrode layer 172 may overlap each other. However, even when the lower reflective electrode layer 171 and the side reflective electrode layer 172 overlap each other, as illustrated in FIG. 10, the lower reflective electrode layers 171 are not physically in contact with and spaced apart from each other. Because the lower reflective electrode layers 171 are spaced apart from each other in the horizontal direction, each light emitting device may be prevented from being short-circuited.

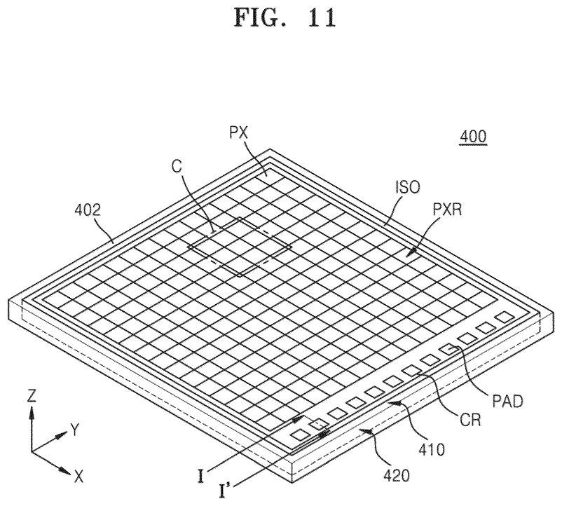

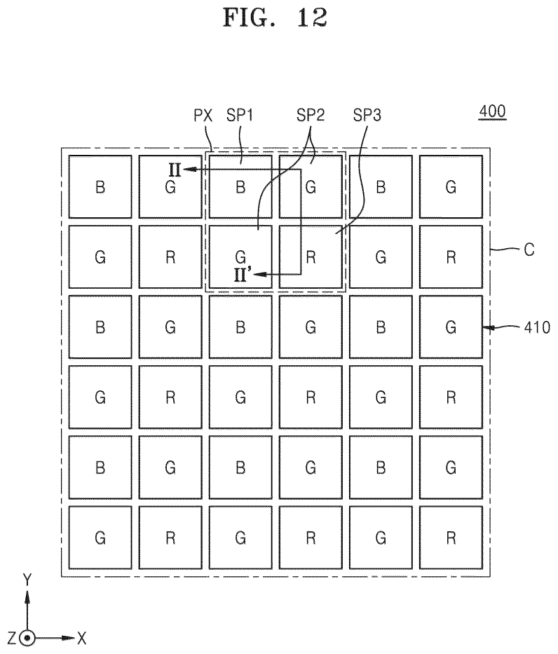

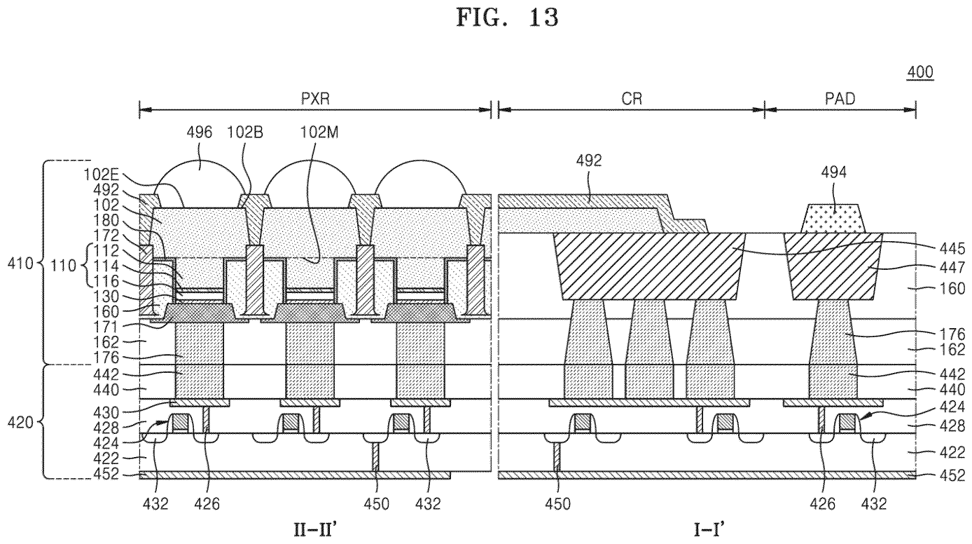

FIG. 11 is a schematic perspective view illustrating a display device 400 according to one or more embodiments. FIG. 12 is an enlarged plan view of a portion indicated by “C” in FIG. 11. FIG. 13 is a cross-sectional view schematically illustrating components of a cross-section taken along line I-I′ of FIG. 11 and a cross-section taken along line II-II′ of FIG. 12. In FIGS. 11 to 13, the same reference numerals as in FIG. 1 denote the same members, and detailed descriptions thereof will be omitted.

Referring to FIGS. 11 to 13, the display device 400 may include a pixel array 410 and a circuit board 420 arranged to overlap in a vertical direction (Z direction in FIG. 11). The circuit board 420 may include driving circuits. The pixel array 410 may include a plurality of pixels PX arranged in a pixel region PXR on the circuit board 420. The display device 400 may further include a frame 402 adjacent to and surrounding the pixel array 410 and the circuit board 420.

The circuit board 420 may be a driving circuit board including a plurality of transistors. In one or more embodiments, the circuit board 420 may include an application-specific integrated circuit (ASIC) having a plurality of driver circuits. In one or more embodiments, the circuit board 420 may include a flexible board. In this case, the display device 400 may be implemented as a variable or curved display device.

The pixel array 410 may include the pixel region PXR in which the plurality of pixels PX are arranged, a plurality of connection pad regions PAD in which a plurality of connection pad electrodes 494 are arranged, a connection region CR for interconnecting the plurality of pixels PX and the plurality of connection pad electrodes 494, and an edge region ISO.

The plurality of pixels PX may include a plurality of first sub-pixels SP1, a plurality of second sub-pixels SP2, and a plurality of third sub-pixels SP3 each configured to emit light of a specific wavelength, for example, light of a specific color. Each of the plurality of first sub-pixels SP1, the plurality of second sub-pixels SP2, and the plurality of third sub-pixels SP3 may include a light emitting device having the same configuration as described for the semiconductor light emitting structure 110 with reference to FIG. 1.

In one or more embodiments, the first to third sub-pixels SP1, SP2, and SP3 may emit red (R) light, green (G) light, and blue (B) light, respectively. In one or more embodiments, each of the plurality of pixels PX may include first to third sub-pixels SP1, SP2, and SP3 arranged in a Bayer pattern. That is, each of the plurality of pixels PX may include first and third sub-pixels SP1 and SP3 arranged in a first diagonal direction and two second sub-pixels SP2 arranged in a second diagonal direction intersecting the first diagonal direction. In FIG. 12, the first to third sub-pixels SP1, SP2, and SP3 are arranged in a 2×2 Bayer pattern in each of the plurality of pixels PX. However, embodiments are not limited thereto. For example, each of the plurality of pixels PX may be arranged in a different array such as 3×3 or 4×4. In one or more other embodiments, some of the plurality of pixels PX may emit light of a color other than red (R), green (G), and blue (B), for example, yellow (Y). In the pixel array 410 of FIG. 11, the plurality of pixels PX are illustrated as being arranged in a 15×15 array in column and row directions. However, embodiments are not limited thereto. The pixel array 410 may include any suitable number of pixels PX, for example, a plurality of pixels PX arranged in a 1,024×768 array in the column and row directions.

The plurality of connection pad regions PAD may be arranged along an edge of the display device 400 on at least one side of the pixel region PXR. The plurality of connection pad regions PAD may be electrically connected to the plurality of pixels PX and the driving circuits of the circuit board 420. An external device and the display device 400 may be electrically connected through the plurality of connection pad regions PAD. The number of connection pad regions PAD included in the display device 400 may vary. In one or more embodiments, the number of connection pad regions PAD included in the display device 400 may be determined according to the number of pixels PX included in the pixel array 410 and a driving method of the driving circuits included in the circuit board 420.

The connection region CR may be positioned between the pixel region PXR and the plurality of connection pad regions PAD. A wiring structure electrically connected to the plurality of pixels PX, for example, part of a grid electrode 492 illustrated in FIG. 13 and a common electrode 445 may be arranged in the connection region CR.

The edge region ISO of the display device 400 may be arranged along edges of the pixel array 410. The semiconductor light emitting structure 110 may not be arranged in the edge region ISO.

The frame 402 of the display device 400 may be arranged around the pixel array 410 to serve as a guide for defining an arrangement space of the pixel array 410. The frame 402 may include a polymer, ceramic, a semiconductor, a metal, or a combination thereof.

As illustrated in FIG. 13, the circuit board 420 may include a semiconductor substrate 422, a driving circuit including a plurality of driving elements 424 formed on the semiconductor substrate 422 and including transistors, a plurality of interconnecting portions 426 electrically connected to the plurality of driving elements 424, and a plurality of wiring lines 430 connected to the plurality of interconnecting portions 426. The plurality of driving elements 424 constituting the driving circuit, the plurality of interconnecting portions 426, and the plurality of wiring lines 430 may be covered with an insulating layer 428. The circuit board 420 may further include a first bonding insulating layer 440 on the insulating layer 428 and a plurality of first bonding electrodes 442 connected to the plurality of wiring lines 430 through the first bonding insulating layer 440.

The semiconductor substrate 422 may include a plurality of impurity regions 432 constituting source/drain regions of a plurality of transistors constituting the plurality of driving elements 424. The semiconductor substrate 422 may include a semiconductor such as silicon (Si) or germanium (Ge), or a compound semiconductor such as silicon germanium (SiGe), silicon carbide (SiC), gallium arsenide (GaAs), indium arsenide (InAs), or indium phosphide (InP). The semiconductor substrate 422 may further include a plurality of through electrodes 450 such as a through silicon via (TSV) connected to the driving circuit and a plurality of substrate wiring lines 452 connected to the plurality of through electrodes 450.

The driving circuit may be for controlling driving of the pixel PX or the first to third sub-pixels SP1, SP2, and SP3. Some of the plurality of impurity regions 432 may be electrically connected to at least one selected from the plurality of first to third sub-pixels SP1, SP2, and SP3 through the interconnecting portion 426, the wiring line 430, and the first bonding electrode 442. In one or more embodiments, some of the plurality of impurity regions 432 may be connected to one of the plurality of substrate wiring lines 452 through the through electrode 450.

Top surfaces of the plurality of first bonding electrodes 442 and a top surface of the first bonding insulating layer 440 may form a top surface of the circuit board 420. The plurality of first bonding electrodes 442 included in the circuit board 420 may be bonded to a plurality of second bonding electrodes 176 included in the pixel array 410 to provide an electrical connection path. In embodiments, each of the plurality of first bonding electrodes 442 and the plurality of second bonding electrodes 176 may include a copper (Cu) layer. Each of the plurality of first bonding electrodes 442 and the plurality of second bonding electrodes 176 may further include a barrier metal layer surrounding the Cu layer. The barrier metal layer may include Ta, TaN, or a combination thereof.

The first bonding insulating layer 440 included in the circuit board 420 may be bonded to a second bonding insulating layer 162 included in the pixel array 410. Each of the first bonding insulating layer 440 and the second bonding insulating layer 162 may include SiO, SiN, silicon carbon nitride (SiCN), silicon oxycarbide (SiOC), SiON, silicon oxycarbonitride (SiOCN), or a combination thereof.

In the pixel array 410, each of the first to third sub-pixels SP1, SP2, and SP3 may include the semiconductor light emitting structure 110 as described with reference to FIG. 1. For example, the pixel array 410 may include the first conductivity type base semiconductor layer 102 having the main surface 102M and the rear surface 102B opposite to each other and the plurality of semiconductor light emitting structures 110 arranged on the main surface 102M of the first conductivity type base semiconductor layer 102. The plurality of semiconductor light emitting structures 110 may be spaced apart from one another in the horizontal direction parallel to the main surface 102M of the first conductivity type base semiconductor layer 102. Each of the plurality of semiconductor light emitting structures 110 may include the first conductivity type semiconductor layer 112, the active layer 114, and the second conductivity type semiconductor layer 116 sequentially stacked in the vertical direction perpendicular to the main surface 102M of the first conductivity type base semiconductor layer 102. Detailed configurations of the first conductivity type semiconductor layer 112, the active layer 114, and the second conductivity type semiconductor layer 116 are as described with reference to FIG. 1.

The pixel array 410 may further include the grid electrode 492 penetrating the first conductivity type base semiconductor layer 102 in the vertical direction. The grid electrode 492 may include a grid-shaped metal layer. The grid electrode 492 may be in physical contact with the side reflective electrode layer 172. Therefore, the grid electrode 492 and the side reflective electrode layer 172 may operate as the same electrode. In the present specification, the grid electrode 492 may also be referred to as the first electrode identical to the side reflective electrode layer 172. The grid electrode 492 may include local regions extending along regions among the plurality of semiconductor light emitting structures 110 from a planar perspective parallel to the main surface 102M of the first conductivity type base semiconductor layer 102, and the local regions of the grid electrode 492 may be connected to one another to form a single layer and may be arranged to surround the plurality of semiconductor light emitting structures 110. The local regions of the grid electrode 492 may be connected to one another to form a grid shape or a mesh shape. In this way, the grid electrode 492 is arranged to fill spaces among the plurality of semiconductor light emitting structures 110, thereby improving current spreading and thus improving light emitting efficiency in the pixel array 410 of the display device 400. In one or more embodiments, by forming the grid electrode 492 by a plating process, relatively narrow spaces among the plurality of semiconductor light emitting structures 110 may be more stably filled with the grid electrode 492.

Part of the grid electrode 492 may be in contact with a sidewall of the first conductivity type base semiconductor layer 102. Another part of the grid electrode 492 may be in contact with the rear surface 102B of the first conductivity type base semiconductor layer 102 to define the light emitting surface 102E formed as part of the rear surface 102B of the first conductivity type base semiconductor layer 102. In embodiments, the grid electrode 492 may include Ag, Ni, Al, Cr, Rh, Ir, Pd, Ru, Mg, Zn, Pt, Au, or a combination thereof.

A plurality of microlenses 496 may each be arranged on the light emitting surface 102E defined by the grid electrode 492 in the rear surface 102B of the first conductivity type base semiconductor layer 102. The plurality of microlenses 496 may each be in contact with a portion of the grid electrode 492 provided on and covering the rear surface 102B. The plurality of microlenses 496 may be arranged to overlap the plurality of semiconductor light emitting structures 110 in a direction perpendicular to the main surface 102M of the first conductivity type base semiconductor layer 102. A more detailed configuration of the plurality of microlenses 496 is substantially the same as that described for the microlenses 190 with reference to FIG. 8.

The plurality of semiconductor light emitting structures 110 included in the pixel array 410 of the display device 400 may be configured to emit light having a wavelength λ selected in a range of about 400 nm to about 700 nm, for example, a wavelength λ selected in a range of about 490 nm to about 700 nm. The shortest distance from the transparent electrode layer 130 to the active layer 114 in a direction perpendicular to the main surface 102M of the first conductivity type base semiconductor layer 102 may be determined according to the wavelength λ of light emitted from the semiconductor light emitting structure 110.

The display device 400 may further include a common electrode 445 and an internal pad electrode 447. The insulating layer 160 provided on and covering the reflective electrode layer 170 in the pixel array 410 may extend to the connection region CR and the connection pad region PAD to be provided on and cover the common electrode 445 and the internal pad electrode 447.

The grid electrode 492 may extend from the pixel region PXR to the connection region CR, and may be in physical contact with the first conductivity type base semiconductor layer 102 and the common electrode 445 in the connection region CR. The grid electrode 492 may be electrically connected to the first conductivity type base semiconductor layer 102 and the common electrode 445. The connection pad electrode 494 may be arranged on the internal pad electrode 447 in the connection pad region PAD.

The plurality of second bonding electrodes 176 may be connected to the common electrode 445. The common electrode 445 may have a ring shape or a square ring shape adjacent to and surrounding the pixel region PXA from a planar perspective parallel to the main surface 102M of the first conductivity type base semiconductor layer 102. However, the arrangement of the common electrode 445 may be modified and changed in various ways as needed.

In the connection pad region PAD, the connection pad electrode 494 may be arranged on the internal pad electrode 447. The internal pad electrode 447 may be in contact with the connection pad electrode 494. The internal pad electrode 447 may be between the connection pad electrode 494 and the second bonding electrode 176 to interconnect the connection pad electrode 494 and the second bonding electrode 176. The common electrode 445 and the internal pad electrode 447 may include a conductive material, for example, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), or a combination thereof.

The connection pad electrode 494 may be connected to an external device or an external circuit (IC) capable of applying an electrical signal to the circuit board 420 by wire bonding or anisotropic conductive film (AFC) bonding. The connection pad electrode 494 may electrically connect the driving circuits of the circuit board 420 to the external device. The connection pad electrode 494 may include a metal, for example, Au, Ag, or Ni.

Among the plurality of second bonding electrodes 176, the second bonding electrode 176 arranged in the pixel region PXR may be connected to the reflective electrode layer 170, the second bonding electrode 176 arranged in the connection region CR may be connected to the common electrode 445, and the second bonding electrode 176 arranged in the connection pad region PAD may be connected to the internal pad electrode 447. The grid electrode 492 may be connected to the plurality of second bonding electrodes 176 through the common electrode 445.

A surface of the second bonding insulating layer 162 facing the circuit board 420 and surfaces of the plurality of second bonding electrodes 176 facing the circuit board 420 may extend in one plane. The second bonding insulating layer 162 may perform dielectric-dielectric bonding with the first bonding insulating layer 440. The circuit board 420 and the pixel array 410 may be bonded by bonding the plurality of first bonding electrodes 442 and the plurality of second bonding electrodes 176 and by bonding the first bonding insulating layer 440 and the second bonding insulating layer 162.

In one or more embodiments, the bonding of the plurality of first bonding electrodes 442 and the plurality of second bonding electrodes 176 may be, for example, Cu—Cu bonding, and the bonding of the first bonding insulating layer 440 and the second bonding insulating layer 162 may be, for example, dielectric-dielectric bonding such as SiCN-SiCN bonding. The circuit board 420 and the pixel array 410 may be bonded by hybrid bonding including Cu-Cu bonding and dielectric-dielectric bonding, and may be bonded without a separate adhesive layer.

The display device 400 according to one or more embodiments includes the plurality of semiconductor light emitting structures 110. By controlling the thickness of the second conductivity type semiconductor layer 116 according to the wavelength of light emitted from the plurality of semiconductor light emitting structures 110, the active layer 114 in each of the plurality of semiconductor light emitting structures 110 may be arranged at a position at which the LEE of the light emitting device 100 may be optimized. Therefore, the LEE may be maximized in the pixel region PXA of the display device 400. In addition, in the pixel region PXA of the display device 400, the semiconductor light emitting structure 110 constitutes a micro LED having a width of about 100 μm or less so that the active layer 114 in the semiconductor light emitting structure 110 may have a multi-quantum well structure so as to be optimized for a micro-sized chip including the micro LED. Therefore, the display device 400 having a structure that may be optimized for the micro-sized chip may be provided.

FIGS. 14 to 25 are cross-sectional views illustrating a method of manufacturing a display device including a light emitting device according to one or more embodiments according to a process order. A method of manufacturing the display device 400 illustrated in FIGS. 11, 12, and 13 will be described with reference to FIGS. 14 to 25. In FIGS. 14 to 25, the same reference numerals as in FIGS. 1 and 13 denote the same members, and detailed descriptions thereof will be omitted.

Referring to FIG. 14, a structure, in which the first conductivity type base semiconductor layer 102, the plurality of semiconductor light emitting structures 110 arranged in the pixel region PXR and each including the first conductivity type semiconductor layer 112, the active layer 114, and the second conductivity type semiconductor layer 116, and the plurality of transparent electrode layers 130 provided on and covering the plurality of semiconductor light emitting structures 110 are arranged on a growth substrate 401, may be formed by using a semiconductor single crystal growth process, a deposition process, and an etching process using the growth substrate 401.

The growth substrate 401 for semiconductor single crystal growth may include AlN, AlGaN, ZnO, GaAs, MgAl2O4, MgO, LiAlO2, LiGaO2, GaN, or a combination thereof. In one or more embodiments, in order to improve crystallinity and LEE of semiconductor layers, at least a portion of a top surface of the growth substrate 401 may have an uneven structure. In this case, unevenness may also be formed in the layers growing on the growth substrate 401.

In one or more embodiments, in order to form the structure illustrated in FIG. 14, after the first conductivity type base semiconductor layer 102, the first conductivity type semiconductor layer 112, the active layer 114, and the second conductivity type semiconductor layer 116 are sequentially formed on the growth substrate 401, and the transparent electrode layer 130 is formed on the second conductivity type semiconductor layer 116, part of each of the transparent electrode layer 130, the second conductivity type semiconductor layer 116, the active layer 114, and the first conductivity type semiconductor layer 112 is etched by an etching process using a hard mask pattern as an etching mask so that the plurality of semiconductor light emitting structures 110 spaced apart from one another on the first conductivity type base semiconductor layer 102 and the plurality of transparent electrode layers 130 provided on and covering the plurality of semiconductor light emitting structures 110 may remain. The plurality of semiconductor light emitting structures 110 may form a plurality of pillar shapes having a circular, elliptical, or polygonal planar shape together with the plurality of transparent electrode layers 130.

The first conductivity type base semiconductor layer 102, the first conductivity type semiconductor layer 112, the active layer 114, and the second conductivity type semiconductor layer 116 may be formed by a metal organic chemical vapor deposition (MOCVD) process, a hydride vapor phase epitaxy (HVPE) process, or a molecular beam epitaxy (MBE) process. Constituent materials and thicknesses of the first conductivity type base semiconductor layer 102, the first conductivity type semiconductor layer 112, the active layer 114, and the second conductivity type semiconductor layer 116 are as described with reference to FIG. 1.

In one or more embodiments, a wet etching process may be further performed to remove damaged regions due to etching from the plurality of semiconductor light emitting structures 110. By controlling process conditions so that crystal planes are etched with different selectivities in the wet etching process, only damaged regions may be selectively removed from the plurality of semiconductor light emitting structures 110, and sidewalls of each of the plurality of semiconductor light emitting structures 110 may have a profile extending in the vertical direction with respect to the main surface 102M of the first conductivity type base semiconductor layer 102. In addition, non-radiative recombination due to the damaged regions in the sidewalls of each of the plurality of semiconductor light emitting structures 110 is reduced, so that brightness of the light emitting device to be formed may be improved.

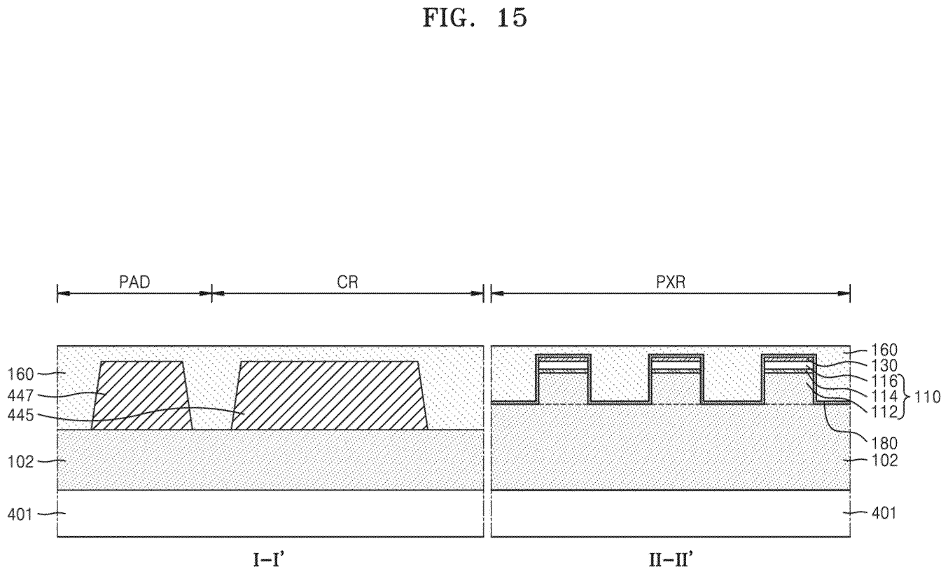

Referring to FIG. 15, after the etch stopper 180 provided on and covering surfaces of the first conductivity type base semiconductor layer 102, the plurality of semiconductor light emitting structures 110, and the plurality of transparent electrode layers 130 is formed in the result of FIG. 14, part of the etch stopper 180 is removed from the connection region CR and the connection pad region PAD to expose the first conductivity type base semiconductor layer 102, and the exposed first conductivity type base semiconductor layer 102 is removed by partial thickness to reduce the thickness of the first conductivity type base semiconductor layer 102 in the connection region CR and the connection pad region PAD.

Thereafter, the common electrode 445 arranged on the first conductivity type base semiconductor layer 102 in the connection region CR and the internal pad electrode 447 arranged on the first conductivity type base semiconductor layer 102 in the connection pad region PAD may be formed. Thereafter, the insulating layer 160 provided on and covering the obtained result may be formed. The insulating layer 160 may be provided on and cover the etch stopper 180 in the pixel region PXR and to be provided on and cover the common electrode 445 and the internal pad electrode 447 in the connection region CR and the connection pad region PAD. The insulating layer 160 may have a flat top surface. Therefore, the insulating layer 160 may be formed after the etch stopper 180 is formed.

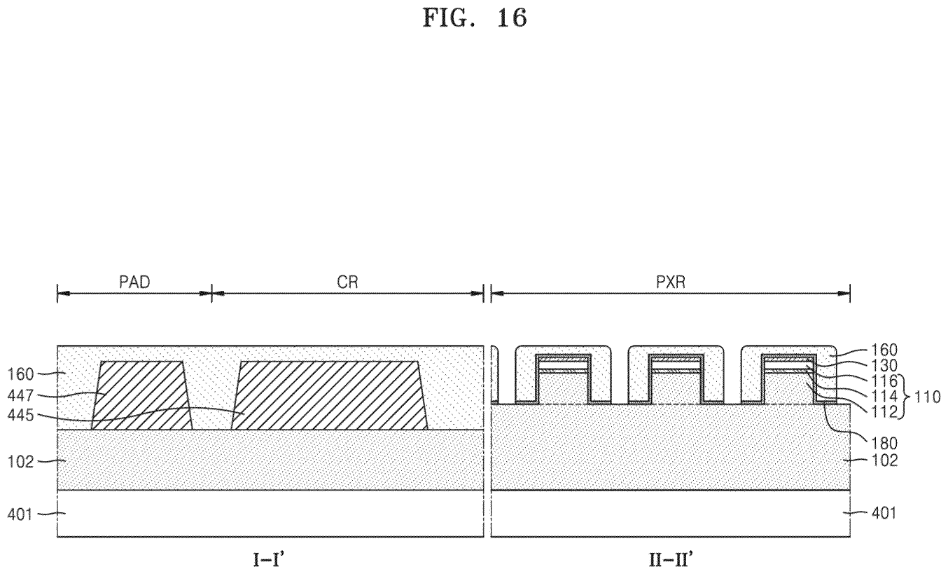

Referring to FIG. 16, in the result of FIG. 15, etching may be performed on a partial region of the insulating layer 160. When performing dry etching of FIG. 16, corners of a top surface of the insulating layer 160 may be rounded. For example, among regions of the insulating layer 160, etching may be performed only on a spacer region formed by the insulating layer 160. It is illustrated in FIGS. 15 and 16 that dry etching is performed only on the spacer region after the insulating layer 160 is formed flatly in the pixel region. However, after a mask corresponding to the spacer region is mounted for the pixel region, the shape of the insulating layer 160 illustrated in FIG. 16 may be deposited directly without a dry etch process. A thickness of a region on which dry etchback is performed is not limited to the drawing.

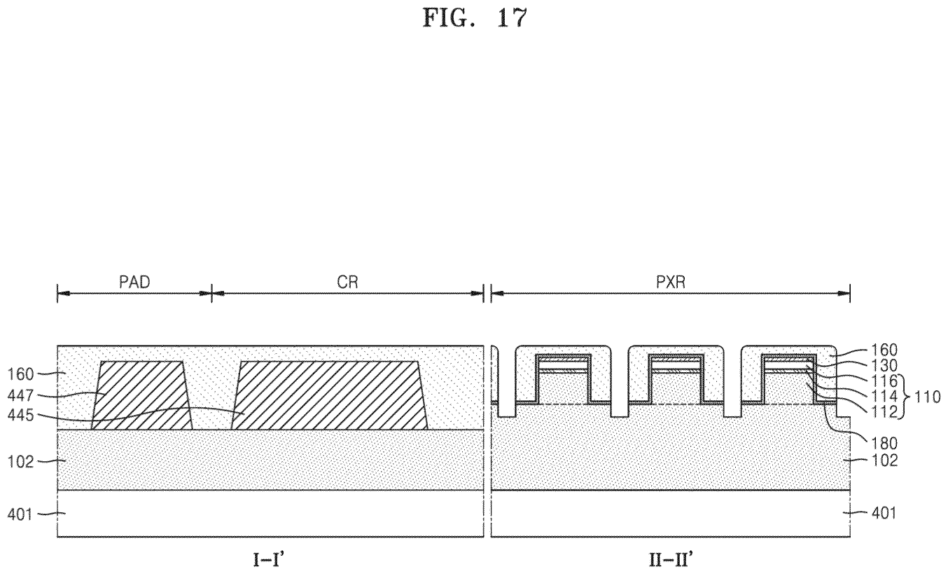

Referring to FIG. 17, in the result of FIG. 16, a partial region of the first conductivity type base semiconductor layer 102 may be etched back. The first conductivity type base semiconductor layer 102 to be etched back may correspond to a region of the insulating layer 160 to be etched back in FIG. 16. Therefore, with respect to the region of the insulating layer 160 etched back in FIG. 16, the region of the first conductivity type base semiconductor layer 102 may be etched back in the vertical direction. Therefore, the insulating layer 160 and the etch stopper 180 may be etched back.

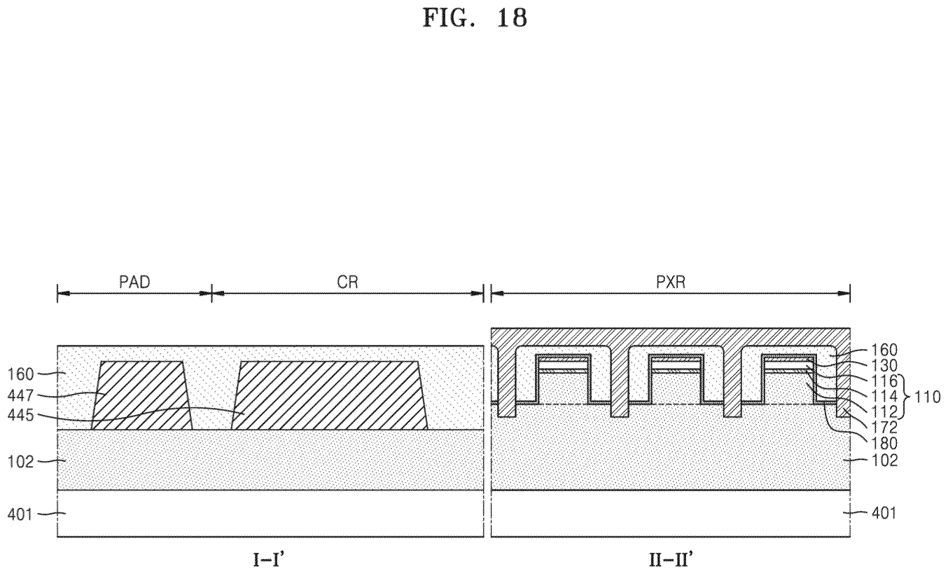

Referring to FIG. 18, in the result of FIG. 17, an electrode layer may be formed. The electrode layer formed in FIG. 18 may be a basic form of the side reflective electrode layer 172. The top surface of the side reflective electrode layer 172 may be constant. The top surface of the side reflective electrode layer 172 may be greater than the top surface of the insulating layer 160. The side reflective electrode layer 172 may be formed only in the pixel region. A plating process may be used to form the side reflective electrode layer 172. However, embodiments are not limited thereto.

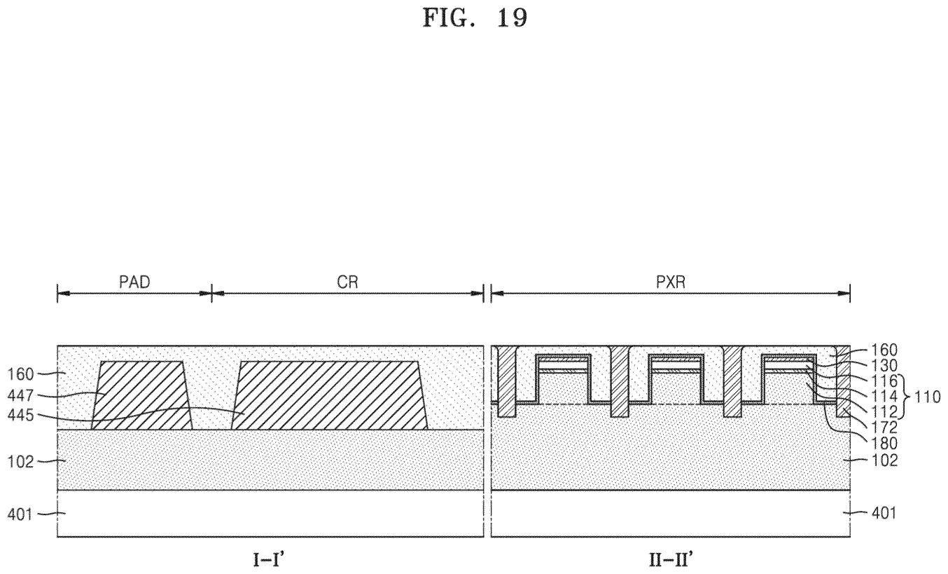

Referring to FIG. 19, in the result of FIG. 18, the top surface of the side reflective electrode layer 172 may be polished. The top surface of the side reflective electrode layer 172 may be removed through chemical mechanical polishing (CMP). The top surface of the side reflective electrode layer 172 may be polished until a vertical level of the top surface of the side reflective electrode layer 172 is the same as a vertical level of the top surface of the insulating layer 160.

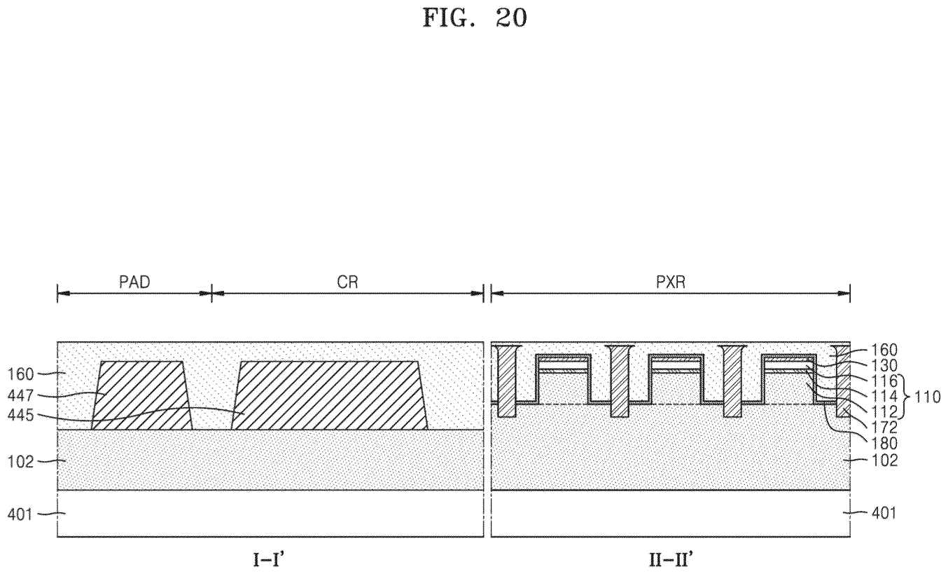

Referring to FIG. 20, in the result of FIG. 19, the insulating layer 160 may be additionally formed. By additionally forming the insulating layer 160 on the top surface of the side reflective electrode layer 172, the polished surface of the side reflective electrode layer 172 may be covered with the insulating layer 160. The polished surface of the side reflective electrode layer 172 may be a bottom surface of the side reflective electrode layer 172. Therefore, the bottom surface of the side reflective electrode layer 172 may be covered with the insulating layer 160.

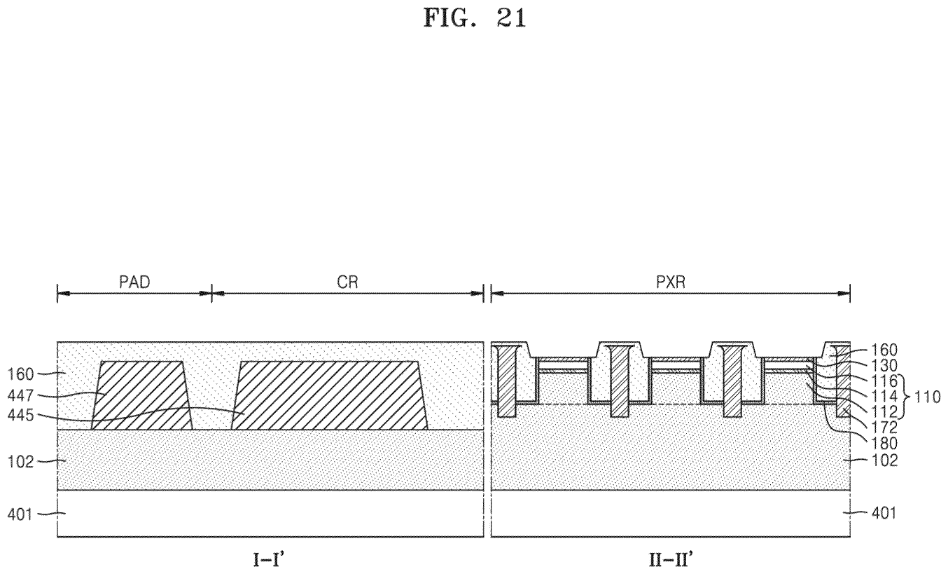

Referring to FIG. 21, in the result of FIG. 20, etching may be performed on a channel region in the pixel region PXR. The channel region may be one surface of the transparent electrode layer 130 included in the semiconductor light emitting structure 110. One surface of the transparent electrode layer 130 may be etched back to be exposed while forming the channel region. Although one surface of the transparent electrode layer 130 is etched back, the entire region of the transparent electrode layer 130 is not removed. At this time, over-etching may be prevented by the etch stopper 180. In the absence of the etch stopper 180, over-etching may occur, and part of the exposed portion of each of the plurality of transparent electrode layers 130 may be etched due to over-etching, thereby forming a local recess on the exposed surface of each of the plurality of transparent electrode layers 130.

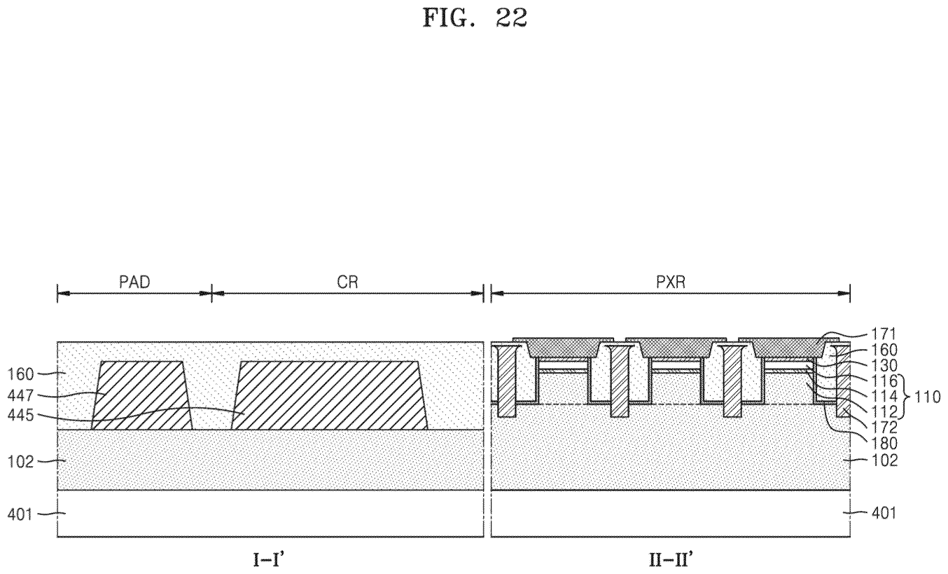

Referring to FIG. 22, in the result of FIG. 21, the lower reflective electrode layer 171 may be formed for the etched channel region. The lower reflective electrode layer 171 may be formed to be provided on and cover at least part of the insulating layer 160 other than the etched channel region. The lower reflective electrode layer 171 may conformally and uniformly be provided on and cover a top surface of the transparent electrode layer 130.

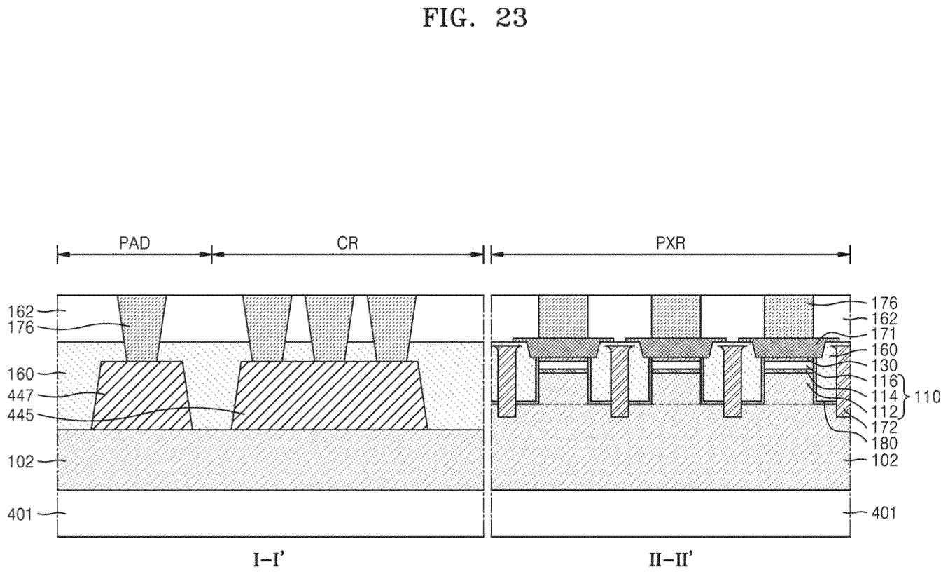

Referring to FIG. 23, in the result of FIG. 22, the second bonding insulating layer 162 provided on and covering the plurality of lower reflective electrode layers 171 and the insulating layer 160 in the pixel region PXR and covering the insulating layer 160 in the connection region CR and the connection pad region PAD may be formed. The second bonding insulating layer 162 may have a flat top surface. After etching part of the second bonding insulating layer 162 in the pixel region PXR, the connection region CR, and the connection pad region PAD to form a plurality of via holes exposing the plurality of lower reflective electrode layers 171, the common electrode 445, and the internal pad electrode 447, the plurality of second bonding electrodes 176 may be formed to fill the plurality of via holes.

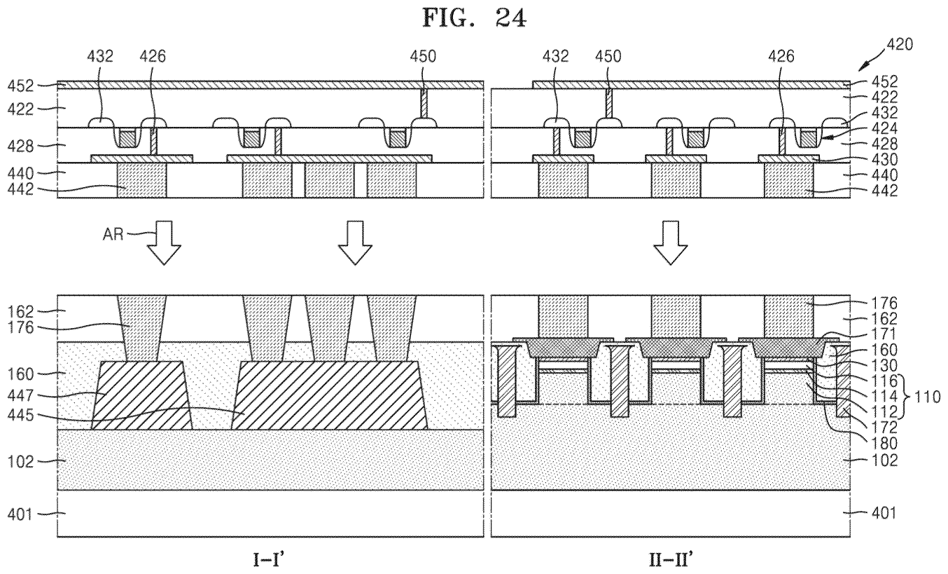

Referring to FIG. 24, after preparing the circuit board 420, the circuit board 420 is positioned on the result of FIG. 23 so that the second bonding insulating layer 162 and the plurality of second bonding electrodes 176 face the first bonding insulating layer 440 and the plurality of first bonding electrodes 442 included in the circuit board 420, respectively, in the result of FIG. 23 and the circuit board 420 may be pressed in a direction of an arrow AR on a surface on which the second bonding insulating layer 162 and the plurality of second bonding electrodes 176 are exposed so that bonding of the plurality of first bonding electrodes 442 and the plurality of second bonding electrodes 176 and bonding of the first bonding insulating layer 440 and the second bonding insulating layer 162 are performed.

The bonding of the plurality of first bonding electrodes 442 and the plurality of second bonding electrodes 176 and the bonding of the first bonding insulating layer 440 and the second bonding insulating layer 162 may be performed by wafer bonding, for example, hybrid bonding described above.

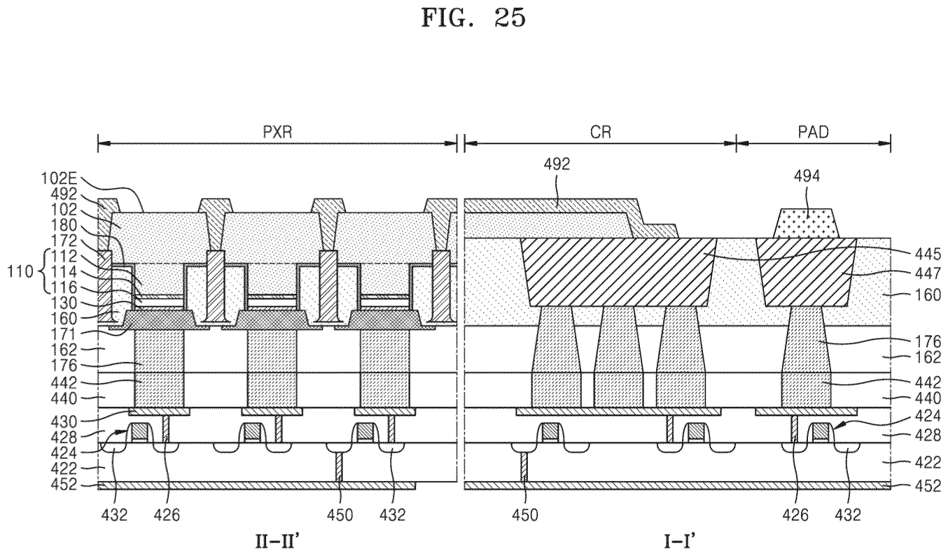

Referring to FIG. 25, in the result in which bonding of the plurality of first bonding electrodes 442 and the plurality of second bonding electrodes 176 and bonding of the first bonding insulating layer 440 and the second bonding insulating layer 162 are performed by the process described with reference to FIG. 24, the growth substrate 401 provided on and covering the first conductivity type base semiconductor layer 102 may be removed to expose the first conductivity type base semiconductor layer 102. The growth substrate 401 may be removed by various processes such as laser lift-off, mechanical polishing or mechanical chemical polishing, or an etching process. After removing the growth substrate 401 to expose the first conductivity type base semiconductor layer 102, the thickness of the first conductivity type base semiconductor layer 102 may be reduced by using a polishing process such as a chemical mechanical polishing (CMP) process.

Thereafter, in the connection region CR and the connection pad region PAD, part of the first conductivity type base semiconductor layer 102 is etched to expose part of the common electrode 445 and the internal pad electrode 447, in the pixel region PXR, partial regions of the first conductivity type base semiconductor layer 102 and partial regions of the reflective structure 150 are etched to prepare a grid-shaped or mesh-shaped electrode space through the first conductivity type base semiconductor layer 102 and the reflective structure 150, and the electrode space is filled with a conductive material to form the grid electrode 492. In the pixel region PXR, the grid electrodes 492 may be formed to be connected to each other in a grid shape or a mesh shape. The grid electrode 492 may be formed up to a portion in physical contact with the side reflective electrode layer 172.

The grid electrode 492 may include a portion provided on and covering the rear surface 102B of the first conductivity type base semiconductor layer 102 in the pixel region PXR and the connection region CR. The grid electrode 492 may be in contact with the first conductivity type base semiconductor layer 102 and the common electrode 445 in the connection region CR. A plating process may be used to form the grid electrode 492. However, embodiments are not limited thereto.

Thereafter, as illustrated in FIG. 13, the plurality of microlenses 496 may be formed to be provided on and cover the plurality of light emitting surfaces 102E defined by the grid electrodes 492 in the rear surface 102B of the first conductivity type base semiconductor layer 102.

The connection pad electrode 494 is formed on the internal pad electrode 447 in the connection pad region PAD and is diced at the edge region ISO (refer to FIG. 11) of each of a plurality of adjacent modules to manufacture the display device 400.

Although a method of manufacturing the display device 400 described with reference to FIGS. 11, 12, and 13 has been described with reference to FIGS. 14 to 25, it will be appreciated by those skilled in the art that the light emitting devices 100, 100a, 100b, and 100c illustrated in FIGS. 1 to 8 may be manufactured by various modifications and changes within the scope of the inventive concept as described with reference to FIGS. 14 to 25.

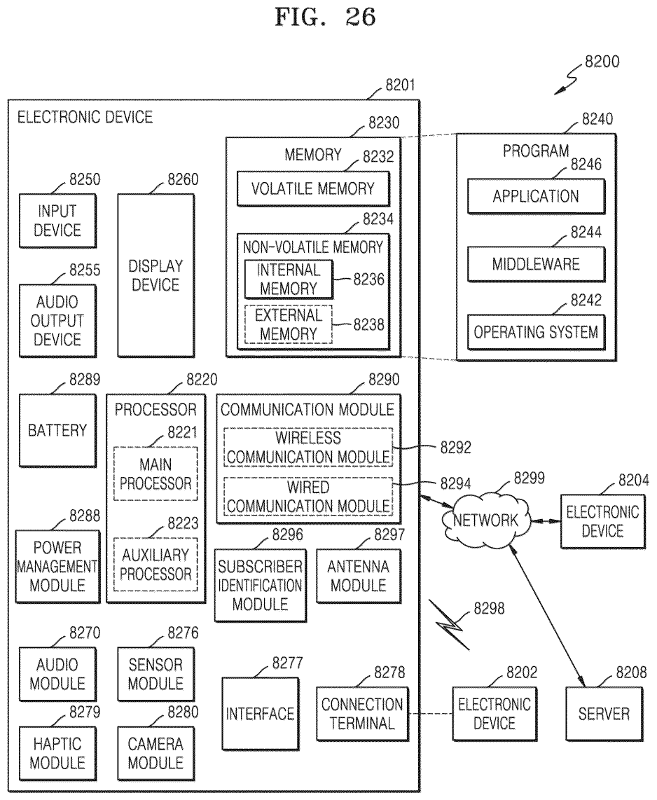

FIG. 26 is a block diagram of one or more embodiments of an electronic device 8201 including a light emitting device or a display device according to one or more embodiments.

Referring to FIG. 26, the electronic device 8201 may be provided in a network environment 8200. In the network environment 8200, the electronic device 8201 may communicate with another electronic device 8202 through a first network 8298 (a short-range wireless communication network) or another electronic device 8204 and/or a server 8208 through a second network 8299 (a long-distance wireless communication network). The electronic device 8201 may communicate with the electronic device 8204 through the server 8208. The electronic device 8201 may include a processor 8220, memory 8230, an input device 8250, an audio output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. Some of the components may be omitted or other components may be added to electronic device 8201. Some of the components may be implemented as one integrated circuit. For example, the sensor module 8276 (such as a fingerprint sensor, an iris sensor, or an illuminance sensor) may be implemented embedded in the display device 8260 (a display).

The processor 8220 may execute software (such as a program 8240) to control one or multiple other components (hardware and software components) of the electronic device 8201 connected to the processor 8220, and may perform a variety of data processing or operations. As part of data processing or operations, the processor 8220 may load commands and/or data received from other components (such as the sensor module 8276 and the communication module 8290) into the volatile memory 8232, may process commands and/or data stored in the volatile memory 8232, and may store resulting data in the non-volatile memory 8234. The processor 8220 may include a main processor 8221 (such as a central processing unit (CPU) or an application processor (AP)) and an auxiliary processor 8223 (such as a graphics processing unit (GPU), an image signal processor, a sensor hub processor, or a communication processor) that may operate independently or together with the main processor 8221. The auxiliary processor 8223 may use less power than the main processor 8221 and may perform a specialized function.

The auxiliary processor 8223 may control functions and/or states related to some (such as the display device 8260, the sensor module 8276, and the communication module 8290) of the components of the electronic device 8201 on behalf of the main processor 8221 while the main processor 8221 is in an inactive state (such as a sleep state) or together with the main processor 8221 while the main processor 8221 is in an active state (such as an application execution state). The auxiliary processor 8223 (such as an image signal processor or a communication processor) may be implemented as part of other functionally related components (such as the camera module 8280 and the communication module 8290).

The memory 2230 may store various data required by components (such as the processor 8220 and the sensor module 8276) of the electronic device 8201. The data may include, for example, input data and/or output data for software (such as the program 8240) and commands related thereto. The memory 8230 may include volatile memory 8232 and/or non-volatile memory 8234.

The program 8240 may be stored as software in the memory 8230, and may include an operating system 8242, middleware 8244, and/or an application 8246.

The input device 8250 may receive commands and/or data to be used for components (such as the processor 8220) of the electronic device 8201 from the outside (such as a user) of the electronic device 8201. The input device 8250 may include a remote controller, a microphone, a mouse, a keyboard, and/or a digital pen (such as a stylus pen).

The audio output device 8255 may output an audio signal to the outside of the electronic device 8201. The audio output device 8255 may include a speaker and/or a receiver. The speaker may be used for general purposes such as multimedia playback or recording playback, and the receiver may be used to receive incoming calls. The receiver may be integrated as part of the speaker or implemented as a separate, independent device.

The display device 8260 may visually provide information to the outside of the electronic device 8201. The display device 8260 may include a display, a hologram device, or a projector, and a control circuit for controlling the device. The display device 8260 may include the light emitting device 100, 100a, 100b, or 100c illustrated in FIGS. 1 to 8 or the display device 400 illustrated in FIGS. 11, 12, and 13. The display device 8260 may include a touch circuitry configured to detect a touch, and/or a sensor circuit (such as a pressure sensor) configured to measure intensity of force generated by the touch.

The audio module 8270 may convert sound into an electrical signal or, conversely, may convert an electrical signal into sound. The audio module 8270 may acquire sound through the input device 8250, or may output sound through the audio output device 8255 and/or a speaker and/or a headphone of another electronic device (such as the electronic device 8202) directly or wirelessly connected to the electronic device 8201.

The sensor module 8276 may detect an operating state (such as power or a temperature) of the electronic device 8201 or an external environmental state (such as a user state), and may generate an electrical signal and/or a data value corresponding to the detected state. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more designated protocols that may be used to connect the electronic device 8201 directly or wirelessly with another electronic device (such as the electronic device 8202). The interface 8277 may include a high definition multimedia interface (HDMI), a universal serial bus (USB) interface, a secure digital (SD) card interface, and/or an audio interface.

A connection terminal 8278 may include a connector by which the electronic device 8201 may be physically connected to another electronic device (for example, the electronic device 8202). The connection terminal 8278 may include an HDMI connector, a USB connector, an SD card connector, and/or an audio connector (such as a headphone connector).

The haptic module 8279 may convert an electrical signal into a mechanical stimulation (such as vibration or movement) or an electrical stimulation that a user may perceive through tactile or kinesthetic sensation. The haptic module 8279 may include a motor, a piezoelectric element, and/or an electrical stimulation device.

The camera module 8280 may capture a still image and a moving image. The camera module 8280 may include a lens assembly including one or more lenses, image sensors, image signal processors, and/or flashes. The lens assembly included in the camera module 8280 may collect light emitted from a subject to be image captured.

The power management module 8288 may manage power supplied to the electronic device 8201. The power management module 8388 may be implemented as part of a power management integrated circuit (PMIC).

The battery 8289 may supply power to the components of the electronic device 8201. The battery 8289 may include a non-rechargeable primary cell, a rechargeable secondary cell, and/or a fuel cell.

The communication module 8290 may support establishment of a direct (wired) communication channel and/or a wireless communication channel between the electronic device 8201 and another electronic device (such as the electronic device 8202, the electronic device 8204, or the server 8208), and communication through the established communication channel. The communication module 8290 may include one or more communication processors that operate independently of the processor 8220 (such as an AP) and support direct communication and/or wireless communication. The communication module 8290 may include a wireless communication module 8292 (such as a cellular communication module, a short-range wireless communication module, or a global navigation satellite system (GNSS)) and/or a wired communication module 8294 (such as a local area network (LAN) communication module or a power line communication module). Among the communication modules, a corresponding communication module may communicate with another electronic device through the first network 8298 (such as a short-range communication network such as Bluetooth, WiFi Direct, or infrared data association (IrDA)) or the second network 8299 (such as a long-range communication network such as a cellular network, the Internet, or a computer network (an LAN or a wide area network (WAN)). The various types of communication modules may be integrated into one component (such as a single chip), or may be implemented as a plurality of separate components (multiple chips). The wireless communication module 8292 may check and authenticate the electronic device 8201 in a communication network such as the first network 8298 and/or the second network 8299 by using subscriber information (such as an international mobile subscriber identifier (IMSI)) stored in the subscriber identification module 8296.

The antenna module 8297 may transmit or receive a signal and/or power to or from the outside (such as another electronic device). The antenna may include a radiator including a conductive pattern formed on a substrate (such as a printed circuit board (PCB)). The antenna module 8297 may include one or multiple antennas. When a plurality of antennas are included, an antenna suitable for a communication method used in a communication network such as the first network 8298 and/or the second network 8299 may be selected from the plurality of antennas by the communication module 8290. Signals and/or power may be transmitted or received between the communication module 8290 and other electronic devices through the selected antenna. In addition to the antenna, other components (such as a radio-frequency integrated circuit (RFIC)) may be included as part of the antenna module 8297.

Some of the components of the electronic device 8201 may be connected to each other through a communication method (such as a bus, general purpose input and output (GPIO), a serial peripheral interface (SPI), or a mobile industry processor interface (MIPI)) between peripheral devices and may exchange signals (such as commands and data).

The commands or data may be transmitted or received between the electronic device 8201 and the electronic device 8204 through the server 8208 connected to the second network 8299. The electronic devices 8202 and 8204 may be the same or different types of devices as or from the electronic device 8201. All or some of the operations executed by the electronic device 8201 may be executed by one or more of the other electronic devices 8202, 8204, and 8208. For example, when electronic device 8201 needs to perform a function or service, the electronic device 8201 may request one or more other electronic devices to perform part or all of the function or service instead of executing the function or service. One or more other electronic devices receiving the request may execute an additional function or service related to the request, and may transmit the result of the execution to the electronic device 8201. For this purpose, cloud computing, distributed computing, and/or client-server computing technologies may be used.

The electronic device 8201 may be applied to various devices. Various components of the electronic device 8201 may be appropriately modified according to the function of the device, and components appropriate for performing the function of the device may be added. Hereinafter, application examples of the electronic device 8201 will be described.

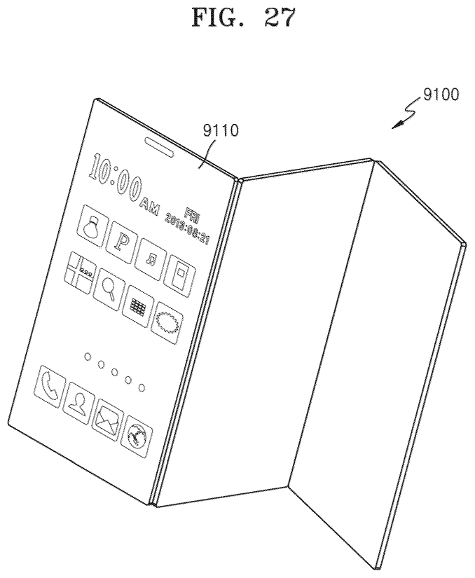

FIG. 27 is a view illustrating one or more embodiments of a mobile device 9100 as an application example of an electronic device including a light emitting device or a display device according to embodiments.

FIG. 27 is a diagram illustrating one or more embodiments of a mobile device as an application example of an electronic device. The mobile device 9100 may include a display device 9110. The display device 9110 may include the light emitting device 100, 100a, 100b, or 100c illustrated in FIGS. 1 to 8 or the display device 400 illustrated in FIGS. 11, 12, and 13. The display device 9110 may have a foldable structure, for example, a multi-foldable structure.

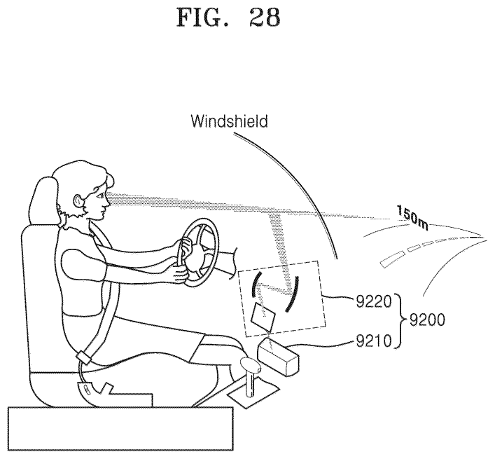

FIG. 28 is a view illustrating one or more embodiments of an automobile head-up display device 9200 as an application example of an electronic device including a light emitting device or a display device according to embodiments.

FIG. 28 is a diagram illustrating one or more embodiments of an automobile head-up display device as an application example of an electronic device. The automobile head-up display device 9200 may include a display 9210 provided in a region of the automobile, and an optical path change member 9220 that converts an optical path so that a driver may view an image generated by the display 9210. The display 9210 may include the light emitting device 100, 100a, 100b, or 100c illustrated in FIGS. 1 to 8 or the display device 400 illustrated in FIGS. 11, 12, and 13.

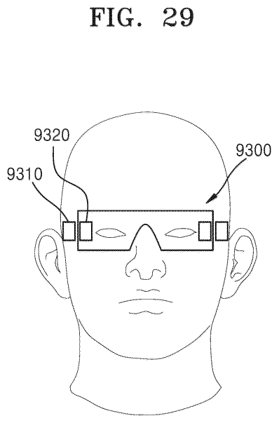

FIG. 29 is a view illustrating one or more embodiments of augmented reality glasses or virtual reality glasses 9300 as an application example of an electronic device including a light emitting device or a display device according to embodiments.

FIG. 29 is a diagram illustrating one or more embodiments of augmented reality glasses or virtual reality glasses as an application example of an electronic device. The augmented reality glasses (or virtual reality glasses) 9300 may include a projection system 9310 forming an image and an element 9320 guiding the image from the projection system 9310 to enter the user's eyes. The projection system 9310 may include the light emitting device 100, 100a, 100b, or 100c illustrated in FIGS. 1 to 8 or the display device 400 illustrated in FIGS. 11, 12, and 13.

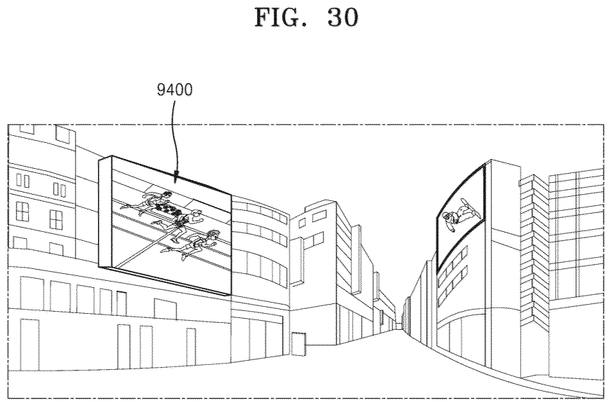

FIG. 30 is a view illustrating one or more embodiments of a large signage 9400 as an application example of an electronic device including a light emitting device or a display device according to embodiments.

FIG. 30 is a diagram illustrating one or more embodiments of a large signage as an application example of an electronic device. The signage 9400 may include the display described with reference to FIG. 12. The signage 9400 may include the light emitting device 100, 100a, 100b, or 100c illustrated in FIGS. 1 to 8 or the display device 400 illustrated in FIGS. 11, 12, and 13. The signage 9400 may be used for outdoor advertising using a digital information display, and may control advertising content through a communication network. The signage 9400 may be implemented, for example, through the electronic device described with reference to FIG. 26.

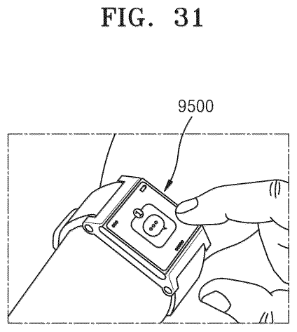

FIG. 31 is a view illustrating one or more embodiments of a wearable display 9500 as an application example of an electronic device including a light emitting device or a display device according to embodiments.

FIG. 31 is a diagram illustrating one or more embodiments of a wearable display as an application example of an electronic device. The wearable display 9500 may include the light emitting device 100, 100a, 100b, or 100c illustrated in FIGS. 1 to 8 or the display device 400 illustrated in FIGS. 11, 12, and 13. The wearable display 9500 may be implemented through the electronic device described with reference to FIG. 26.

The light emitting devices 100, 100a, 100b, and 100c illustrated in FIGS. 1 to 8 or the display device 400 illustrated in FIGS. 11, 12, and 13 may be applied to various products such as a rollable TV and a stretchable display in addition to the electronic devices illustrated above.

While embodiments have been described with reference to the figures, it will be understood by those of ordinary skill in the art that various changes in form and details may be made therein without departing from the spirit and scope as defined by the following claims and their equivalents.

What is claimed is:

1. A light emitting device comprising:
a semiconductor light emitting structure comprising a first conductivity type semiconductor layer, an active layer, and a second conductivity type semiconductor layer sequentially stacked in a vertical direction; and
an electrode layer configured on the second conductivity type semiconductor layer and spaced apart from the active layer in the vertical direction, the second conductivity type semiconductor layer being between the electrode layer and the active layer,
wherein the electrode layer comprises:
a transparent electrode layer on the second conductivity type semiconductor layer; and
a lower reflective electrode layer on the transparent electrode layer and spaced apart from the second conductivity type semiconductor layer in the vertical direction, the transparent electrode layer being between the lower reflective electrode layer and the second conductivity type semiconductor layer, and
wherein a minimum width of the lower reflective electrode layer in a horizontal direction orthogonal to the vertical direction is greater than a width of the transparent electrode layer in the horizontal direction.

2. The light emitting device of claim 1, further comprising:
an insulating layer on the semiconductor light emitting structure; and
a side reflective electrode layer spaced apart from the semiconductor light emitting structure in the horizontal direction,
wherein a portion of the side reflective electrode layer penetrates at least a portion of the insulating layer.

3. The light emitting device of claim 2, further comprising a first conductivity type base semiconductor layer integrally connected to the first conductivity type semiconductor layer and spaced apart from the active layer in the vertical direction, the first conductivity type semiconductor layer being between the first conductivity type base semiconductor layer and the active layer,
wherein the first conductivity type semiconductor layer is on a main surface of the first conductivity type base semiconductor layer, and
wherein a level of a top surface of the side reflective electrode layer is greater than a level of the main surface in the vertical direction.

4. The light emitting device of claim 3, wherein a distance between the side reflective electrode layer and the semiconductor light emitting structure is less than a distance between a top surface of the lower reflective electrode layer and the main surface.

5. The light emitting device of claim 2, wherein the side reflective electrode layer is spaced apart from another side reflective electrode layer in the horizontal direction, the semiconductor light emitting structure being between the side reflective electrode layers.

6. The light emitting device of claim 2, wherein a portion of the lower reflective electrode layer and a portion of the side reflective electrode layer overlap each other in the vertical direction.

7. The light emitting device of claim 2, wherein a distance between a center of the side reflective electrode layer and a center of another side reflective electrode layer is greater than a maximum width of the lower reflective electrode layer in the horizontal direction.

8. The light emitting device of claim 1, further comprising an etch stopper on sidewalls of the semiconductor light emitting structure.

9. The light emitting device of claim 8, wherein at least a portion of the etch stopper is in physical contact with the lower reflective electrode layer.

10. The light emitting device of claim 1, wherein a width of the lower reflective electrode layer in the horizontal direction increases away from the transparent electrode layer.

11. A light emitting device comprising:
a first conductivity type base semiconductor layer;
a semiconductor light emitting structure comprising a first conductivity type semiconductor layer, an active layer, and a second conductivity type semiconductor layer sequentially stacked on a main surface of the first conductivity type base semiconductor layer in a vertical direction perpendicular to the main surface;
a transparent electrode layer on the second conductivity type semiconductor layer and spaced apart from the active layer in the vertical direction, the second conductivity type semiconductor layer being between the transparent electrode layer and the active layer;
a lower reflective electrode layer on the transparent electrode layer and spaced apart from the second conductivity type semiconductor layer in the vertical direction, the transparent electrode layer being between the lower reflective electrode layer and the second conductivity type semiconductor layer;
an insulating layer on the semiconductor light emitting structure; and
a side reflective electrode layer spaced apart from the semiconductor light emitting structure in a horizontal direction orthogonal to the vertical direction,
wherein a portion of the side reflective electrode layer penetrates at least a portion of the insulating layer.

12. The light emitting device of claim 11, further comprising a reflective structure on a bottom surface of the semiconductor light emitting structure and a bottom surface the insulating layer,
wherein the reflective structure comprises a distributed Bragg reflector (DBR).

13. The light emitting device of claim 12, wherein the lower reflective electrode layer penetrates at least a portion of the reflective structure.

14. The light emitting device of claim 12, wherein a level of a top surface of the side reflective electrode layer is greater than a level of the main surface in the vertical direction.

15. The light emitting device of claim 12, wherein a bottom surface of the side reflective electrode layer is in physical contact with the reflective structure.

16. The light emitting device of claim 12, wherein a width of the lower reflective electrode layer in the horizontal direction is less than a width of the transparent electrode layer in the horizontal direction.

17. The light emitting device of claim 12, wherein the side reflective electrode layer is spaced apart from another side reflective electrode layer in the horizontal direction, the semiconductor light emitting structure being between the side reflective electrode layers.

18. The light emitting device of claim 11, wherein a width of the lower reflective electrode layer in the horizontal direction increases away from the transparent electrode layer, and
wherein the lower reflective electrode layer comprises silver (Ag), nickel (Ni), aluminum (Al), magnesium (Mg), zinc (Zn), gold (Au), chromium (Cr), titanium (Ti), or a combination thereof.

19. A light emitting device comprising:
a first conductivity type base semiconductor layer;
a semiconductor light emitting structure comprising a first conductivity type semiconductor layer, an active layer, and a second conductivity type semiconductor layer sequentially stacked on a main surface of the first conductivity type base semiconductor layer in a vertical direction perpendicular to the main surface;
a first electrode on sidewalls of the first conductivity type base semiconductor layer;
a transparent electrode layer on the second conductivity type semiconductor layer and spaced apart from the active layer in the vertical direction, the second conductivity type semiconductor layer being between the transparent electrode layer and the active layer;
a lower reflective electrode layer on the transparent electrode layer and spaced apart from the second conductivity type semiconductor layer in the vertical direction, the transparent electrode layer being between the lower reflective electrode layer and the second conductivity type semiconductor layer;
a second electrode on the transparent electrode layer and spaced apart from the second conductivity type semiconductor layer in the vertical direction, the transparent electrode layer being between the second electrode and the second conductivity type semiconductor layer;
an etch stopper on sidewalls of the semiconductor light emitting structure;
an insulating layer on the semiconductor light emitting structure;
a side reflective electrode layer spaced apart from the semiconductor light emitting structure in a horizontal direction orthogonal to the vertical direction; and
a microlens on a portion of a rear surface of the first conductivity type base semiconductor layer opposite to the main surface of the first conductivity type base semiconductor layer, the microlens being configured to extract light emitted from the semiconductor light emitting structure,
wherein a minimum width of the lower reflective electrode layer in the horizontal direction is greater than a width of the transparent electrode layer in the horizontal direction,
wherein a distance between a center of the side reflective electrode layer and a center of another side reflective electrode layer is greater than a maximum width of the lower reflective electrode layer in the horizontal direction,
wherein a portion of the side reflective electrode layer penetrates at least a portion of the insulating layer,
wherein at least a portion of the etch stopper is in physical contact with the lower reflective electrode layer, and
wherein a level of a bottom surface of the transparent electrode layer in the vertical direction is uniform.

20. The light emitting device of claim 19, wherein the insulating layer is on a bottom surface of the side reflective electrode layer.
